(19) United States
(12) Patent Application Publication
(10) Pub. No.: US 2026/0107809 A1
(43) Pub. Date: Apr. 16, 2026

(54) WIRE BONDING APPARATUS

(71) Applicant: Samsung Electronics Co., Ltd., Suwon-si (KR)

(72) Inventors: Younjo MUN, Suwon-si (KR); Byungwook KIM, Suwon-si (KR); Hoyoung SON, Suwon-si (KR); Junghyun LEE, Suwon-si (KR)

(73) Assignee: Samsung Electronics Co., Ltd., Suwon-si (KR)

(21) Appl. No.: 19/262,589

(22) Filed: Jul. 8, 2025

(30) Foreign Application Priority Data
Oct. 10, 2024 (KR) 10-2024-0137784

(51) Int. Cl. H01L 23/00; B23K 20/00; B23K 101/40

(52) U.S. Cl. CPC H10W 72/0711; B23K 20/005; B23K 2101/40; H10W 72/07118; H10W 72/07168; H10W 72/07173

(57) ABSTRACT

A wire bonding apparatus may include a wire supply portion configured to supply a conductive wire, a capillary configured to draw out the conductive wire supplied from the wire supply portion, and a wire holder disposed between the capillary and the wire supply portion. The wire holder has a first clamp and a second clamp that are spaced apart from each other and are configured to clamp the conductive wire. Each of the first clamp and the second clamp has a polygonal column shaped support body having with a plurality of contact surfaces along a circumference of each of the first clamp and the second clamp, and the polygonal column shaped support body is configured to rotate in a circumferential direction about a central axis of the polygonal column shaped support body.

### CROSS-REFERENCE TO RELATED APPLICATIONS

This U.S. non-provisional application claims priority under 35 U.S.C. § 119 to Korean Patent Application No. 10-2024-0137784, filed on Oct. 10, 2024, in the Korean Intellectual Property Office (KIPO), the contents of which are herein incorporated by reference in their entirety.

### BACKGROUND

Example embodiments relate to a wire bonding apparatus including a clamp for a bonding wire.

As diameters of bonding wires used in semiconductor devices decrease, management of clamps used to hold or secure the bonding wires becomes of relative importance. When contaminants (or foreign substances or debris) accumulate on a surface of a clamp, the contaminants may scratch the bonding wires held by the clamp, deform a wire loop made from the bonding wires, or cause other defects in the semiconductor device. Accordingly, it may be beneficial to clean the surface of the clamp. However, cleaning process may involve stopping or pausing the manufacturing process, and this may reduce productivity. In addition, the cleaning process may include physically applying force to remove or dislodge the contaminants from the surface of the clamp, and this may change the position or calibration of the clamp, thereby reducing product quality. Therefore, it is beneficial to increase the time between successive cleaning cycles while maintaining a relatively cleaner surface of the clamp.

### SUMMARY

Example embodiments are directed to a wire bonding apparatus to improve or increase the usage cycle of a clamp, and reduce time spent for maintenance of the clamp and the associated costs.

According to some example embodiments, a wire bonding apparatus includes a wire supply portion configured to supply a conductive wire, a capillary configured to draw out the conductive wire from the wire supply portion, and a wire holder between the capillary and the wire supply portion. The wire holder has a first clamp and a second clamp that are spaced apart from each other and are configured to clamp the conductive wire. Each of the first clamp and the second clamp has a polygonal column shaped support body having a plurality of contact surfaces along a circumference of each of the first clamp and the second clamp, and the support body is configured to rotate in a circumferential direction about a central axis of the support body.

According to some example embodiments, a wire bonding apparatus includes a loading portion configured to hold a substrate, a capillary on the loading portion and configured to draw out a conductive wire onto the substrate, a wire supply portion configured to supply the conductive wire to the capillary, and a wire holder between the capillary and the wire supply portion. The wire holder has a first clamp and a second clamp that are spaced apart from each other and are configured to clamp the conductive wire. The first clamp includes a plurality of first contact surfaces and is configured to rotate about a first central extension line passing through a center of the first clamp, and the second clamp includes a plurality of second contact surfaces spaced from the plurality of first contact surfaces and is configured to rotate about a second central extension line passing through a center of the second clamp.

According to example embodiments, a wire bonding apparatus includes a loading portion configured to fix a substrate, a heater below the loading portion and configured to heat the substrate, a capillary on the loading portion and configured to draw out a conductive wire onto the substrate, a wire supply portion including a spool configured to supply the conductive wire and a plurality of guides configured to transfer the conductive wire from the spool to the capillary, and a wire holder between the capillary and the wire supply portion and configured to hold the conductive wire. The wire holder includes a first clamp having a plurality of first contact surfaces and a second clamp having a plurality of second contact surfaces, the first clamp and the second clamp are spaced apart from each other and are configured to clamp the conductive wire, and each of the first and second clamps includes, a support body configured to rotate about a central axis of the support body, and a rotation shaft protruding from one end portion of the support body along the central axis of the support body, the rotation shaft being integral with the support body and configured to rotate with the support body about the central axis the support body.

According to some example embodiments, a wire bonding apparatus may include a loading portion configured to hold a substrate, a capillary configured to inject a conductive wire to the substrate, a wire supply portion configured to supply the conductive wire to the capillary, and a wire holder between the capillary and the wire supply portion and having a first clamp and a second clamp that are spaced apart from each other and are configured to clamp the conductive wire therebetween.

Each of the first clamp and the second clamp may have a plurality of contact surfaces along a circumstance of each of the first clamp and the second clamp, and configured to rotate about a central axis of each of the first clamp and the second clamp.

According to some example embodiments, since each of the first clamp and the second clamp includes a plurality of contact surfaces, when foreign substances, contaminants or debris is attached to at least one of the plurality of contact surfaces, each of the first clamp and the second clamp may rotate to provide a relatively cleaner surface among the plurality of contact surfaces. Therefore, a cleaning process may not be performed until all of the plurality of contact surfaces are used. Thus, each of the first clamp and the second clamp may improve a productivity of a process and reduce or limit process errors caused by frequent cleaning processes.

According to some example embodiments, the wire holder may include at least one protection tape that is configured to protect the contact surfaces of each of the first clamp and the second clamp.

According to some example embodiments, since the at least one protection tape protects the contact surfaces that are not in contact with the conductive wires, the at least one protection tape may reduce or limit the plurality of contact surfaces from being contaminated by contaminants (e.g., airborne contaminants).

According to some example embodiments, the wire holder may include a pair of cleaning devices each configured to clean contaminated contact surfaces of the plurality of contact surfaces of each of the first clamp and the second clamp.

According to some example embodiments, since the pair of cleaning devices are configured to automatically remove the contaminated contact surfaces, the productivity of the process may be increased, improved, or optimized.

According to some example embodiments, the wire holder may include a measurement device between the first clamp and the second clamp and configured to measure a distance between the first clamp and the second clamp.

According to some example embodiments, since the measurement device is configured to automatically measure the distance between the first clamp and the second clamp, the accuracy and productivity of the process may be improved, increased, or optimized.

According to some example embodiments, a wire bonding method includes moving a pair of clamps away from each other to increase a distance between the pair of clamps, supplying a conductive wire between the pair of clamps and to a capillary positioned below the pair of clamps, and moving the pair of clamps towards each other to contact the conductive wire disposed therebetween. According to some example embodiments, the wire bonding method further includes bonding the conductive wire to a first substrate pad of a substrate positioned below the capillary, moving the capillary to bond the conductive wire to a second substrate pad of the substrate, and cutting the conductive wire by contacting the conductive wire with the pair of clamps. According to some example embodiments, the pair of clamps includes a first clamp and a second clamp, each of the first clamp and the second clamp has a polygonal column shaped support body having a plurality of clamping surfaces along a circumference of each of the first clamp and the second clamp, and first clamping surfaces of each of the first clamp and the second clamp contact the conductive wire, and the method further includes moving the pair of clamps away from each other to separate the first clamping surfaces from the conductive wire, rotating the pair of clamps such that second clamping surfaces of each of the first clamp and the second clamp face each other with the conductive wire disposed therebetween, wherein each second clamping surface is circumferentially adjacent to a corresponding first clamping surface, and moving the pair of clamps towards each other to contact the conductive wire with the second clamping surface of the first clamp and the second clamping surface of the second clamp.

### BRIEF DESCRIPTION OF THE DRAWINGS

FIG. 1 is a cross-sectional view illustrating a wire bonding apparatus according to some example embodiments.

FIG. 2 is an enlarged cross-sectional view illustrating portion ‘M1’ in FIG. 1.

FIG. 3 is a plan view illustrating the first wire holder of the wire bonding apparatus in FIG. 1.

FIGS. 4A and 4B are cross-sectional views illustrating the wire bonding apparatus in FIG. 1.

FIG. 5 is a perspective view illustrating a pair of clamps in FIG. 1.

FIG. 6A is a plan view illustrating support bodies in FIG. 1.

FIGS. 6B, 6C, and 6D are views illustrating virous shapes of support bodies according to some example embodiments.

FIGS. 7, 8, 9, 10, 11, 12, 13, 14, 15, 16, 17, 18, 19, and 20 are views illustrating a wire bonding method according to some example embodiments.

FIG. 21 is a plan view of a second wire holder of a wire bonding apparatus according to some example embodiments.

FIG. 22 is a perspective view illustrating the pair of clamps in FIG. 21.

FIG. 23 is a plan view of a third wire holder of a wire bonding apparatus according to some example embodiments.

FIG. 24 is a cross-sectional view taken along the line C3-C3′ in FIG. 23.

FIG. 25 is a plan view illustrating a wire bonding apparatus according to some example embodiments.

FIG. 26 is a plan view illustrating the wire bonding apparatus in FIG. 25.

FIG. 27 is a cross-sectional view illustrating the wire bonding apparatus in FIG. 25.

### DETAILED DESCRIPTION OF EXAMPLE EMBODIMENTS

Hereinafter, example embodiments will be explained in detail with reference to the accompanying drawings.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it will be understood that precision of the geometric shape is not the intention but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

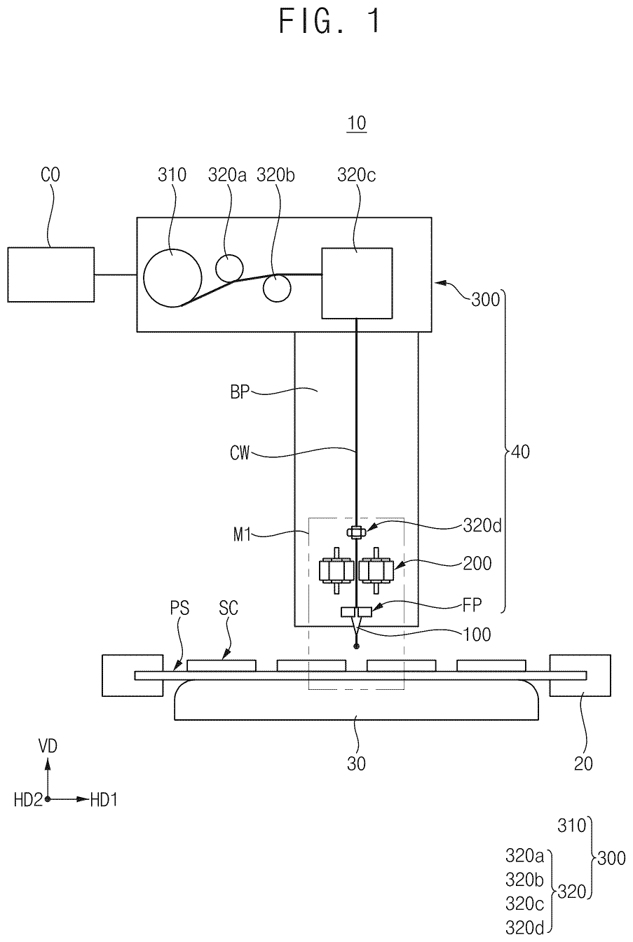

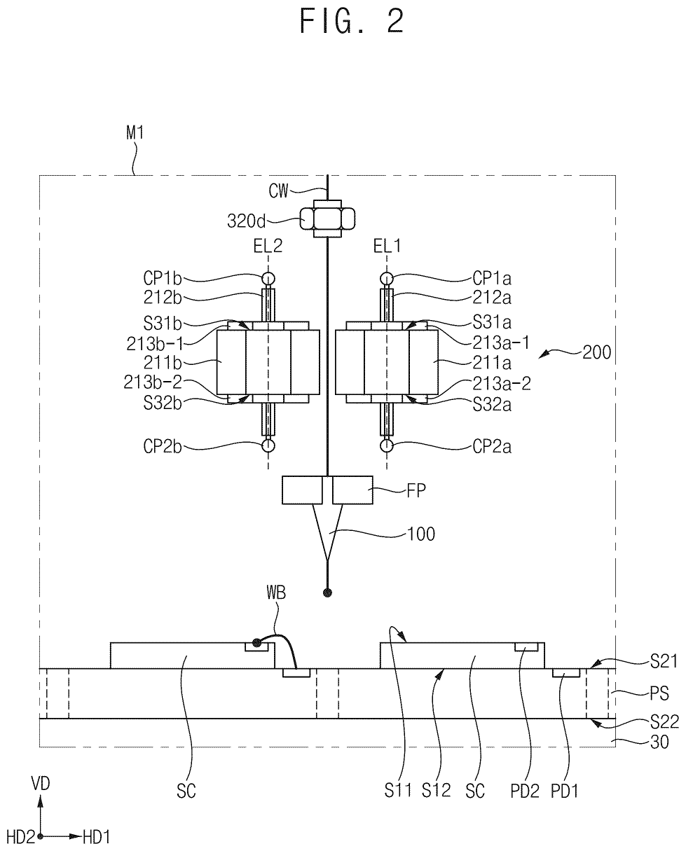

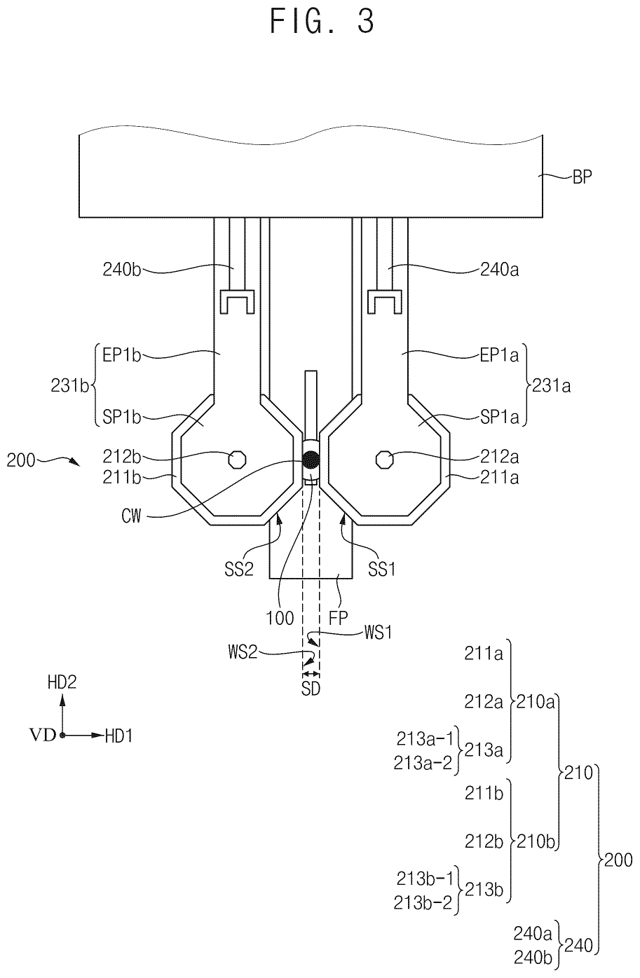

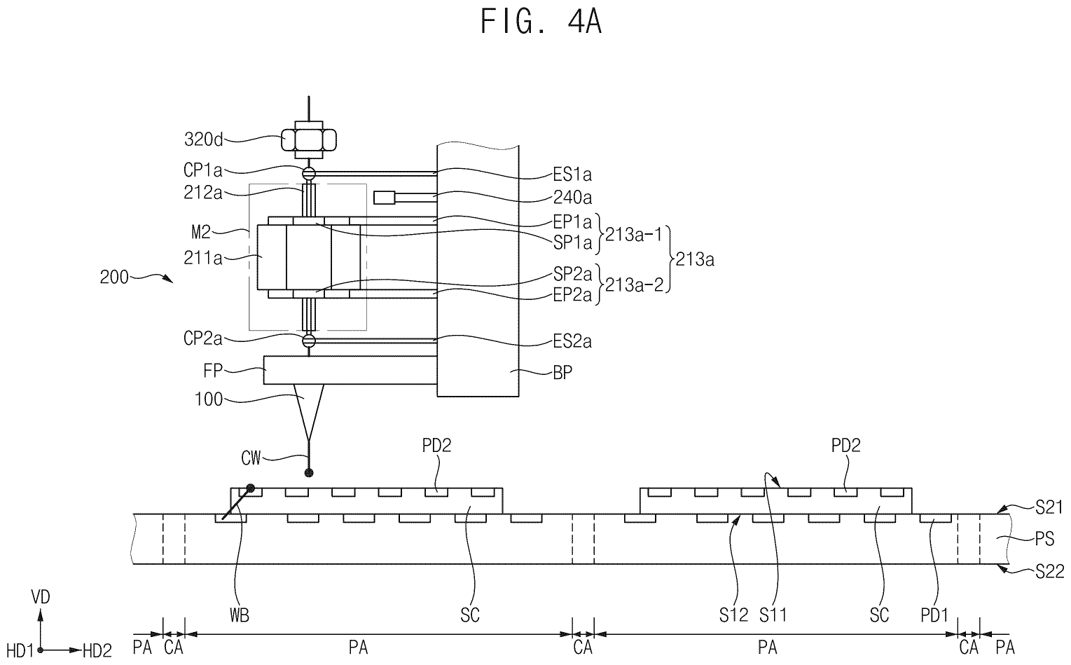

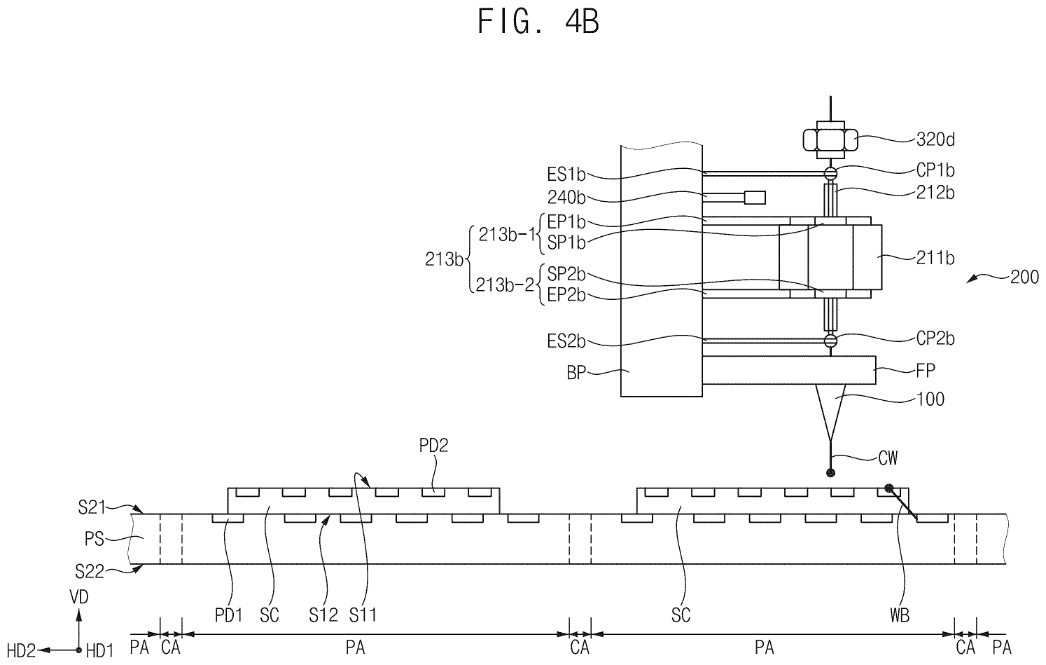

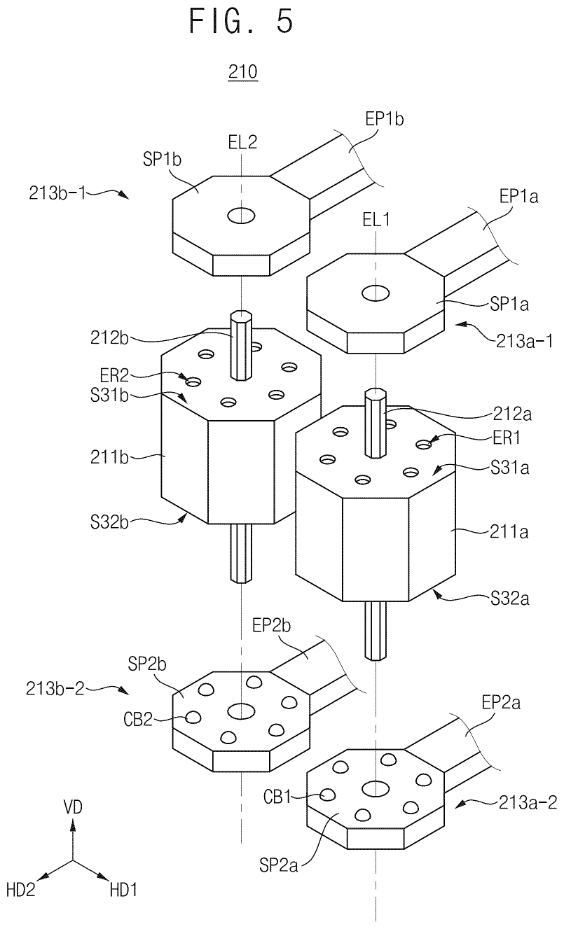

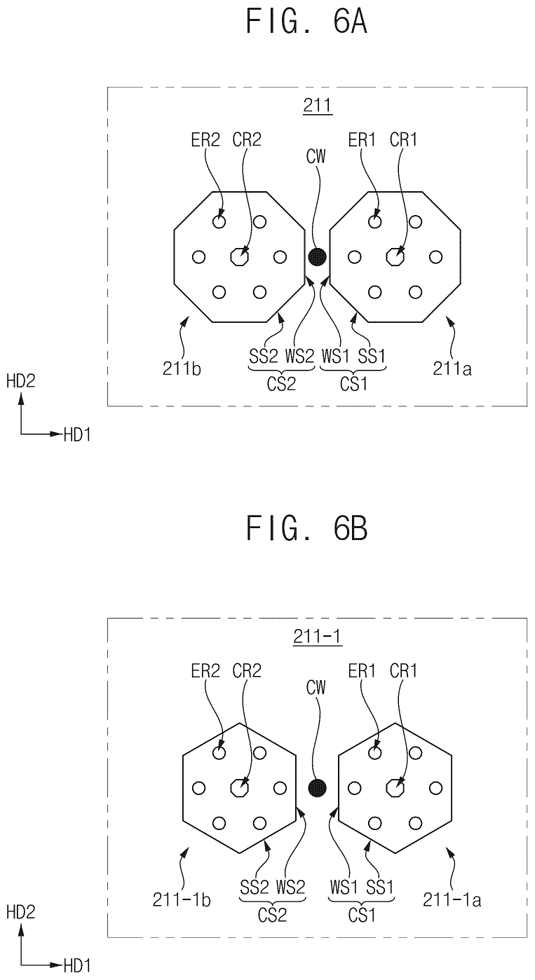

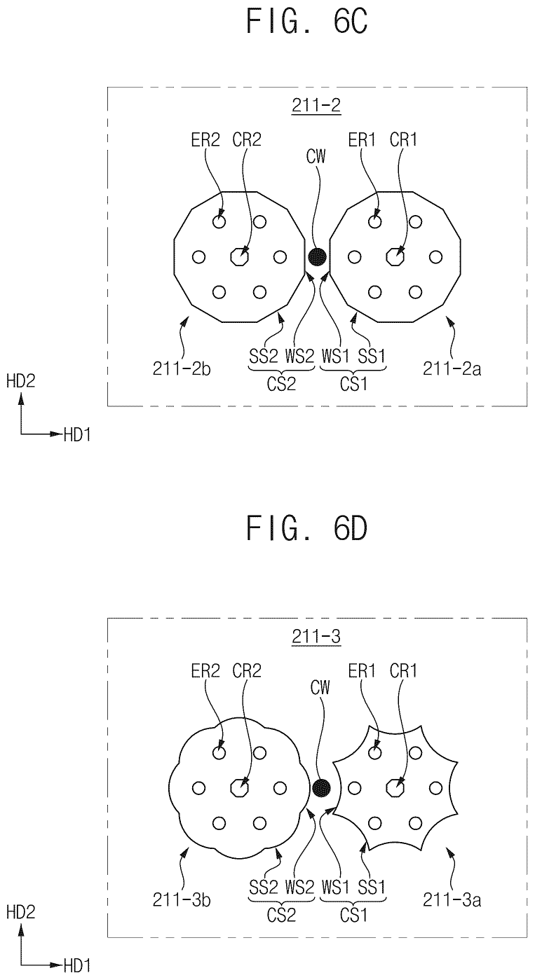

FIG. 1 is a cross-sectional view illustrating a wire bonding apparatus 10 according to some example embodiments. FIG. 2 is an enlarged cross-sectional view illustrating portion ‘M1’ in FIG. 1. FIG. 3 is a plan view illustrating the first wire holder 200 of the wire bonding apparatus 10 in FIG. 1. FIGS. 4A and 4B are cross-sectional views illustrating the wire bonding apparatus in FIG. 1. FIG. 5 is a perspective view illustrating a pair of clamps in FIG. 1. FIG. 6A is a plan view illustrating support bodies in FIG. 1.

Referring to FIGS. 1 to 6A, a wire bonding apparatus 10 may include a loading portion 20 configured to hold or secure a substrate PS, a heater 30 located below the loading portion 20 and configured to heat the substrate PS, and a wire supply module 40 located over the loading portion 20 and configured to supply a conductive wire CW. For example, the wire bonding apparatus 10 may be an apparatus configured to form bonding wires WB (FIG. 2) that electrically connect the substrate PS and a plurality of semiconductor chips SC stacked on the substrate PS.

In some example embodiments, the loading portion 20 may be provided around the substrate PS to support the substrate PS.

For example, the substrate PS may have a first surface S21 and a second surface S22 opposite each other, and may include a plurality of substrate pads PD1 provided on the first surface S21. The substrate PS may include a plurality of mounting regions PA (FIGS. 4A and 4B), in which semiconductor chips are mounted, and a cutting region CA (FIGS. 4A and 4B) surrounding the plurality of mounting regions PA. For example, the cutting region CA may be a portion that is to be removed by a sawing process.

Each of the plurality of semiconductor chips SC may have a first surface S11 and a second surface S12 opposite each other, and may include a plurality of chip pads PD2 provided on the first surface S11. For example, the first surface S11 may be referred to as an active surface, on which a plurality of circuits are formed, and the second surface S12 may be referred to as an inactive surface. For example, each of the plurality of semiconductor chips SC may be provided on the plurality of mounting regions PA of the substrate PS such that the second surface S12 contacts the substrate PS.

For example, the loading portion 20 may hold fixedly an outermost region of the cutting region CA of the substrate PS to support the substrate PS.

In some example embodiments, the heater 30 may be located on a lower portion of the substrate PS (or located below the substrate PS) and be in thermal contact with the second surface S22 of the substrate PS. For example, the heater 30 may include a plurality of heating wires configured to apply heat to the substrate PS.

In some example embodiments, the wire supply module 40 may include a capillary 100 adjacent to the substrate PS and configured to draw out the conductive wire CW onto the substrate PS, a wire supply portion 300 configured to transfer (or inject) the conductive wire CW into the capillary 100, and a first wire holder 200 disposed (or located) between the capillary 100 and the wire supply portion 300 and configured to selectively hold the conductive wire CW. In addition, the wire supply module 40 may include a controller CO configured to control operations of the wire supply module 40 and a driving portion configured to move the wire supply module 40 in response to a control signal from the controller CO. For example, the conductive wire CW may be or include a conductive metallic material for electrically connecting the substrate PS and the plurality of semiconductor chips SC, respectively. For example, the conductive wire may include gold. A thickness of the conductive wire may be 20 μm (or about 20 μm). However, it will be understood that the material and/or the size of the conductive wire are/is not limited thereto and the conductive wire may be or include any desirable conductive material and may be of any size depending on application and/or design.

The wire supply module 40 may include a body portion BP extending in a vertical direction VD. The body portion BP may include a fixed structure FP extending in a second horizontal direction HD2 orthogonal to the vertical direction VD, and first, second, third, and fourth extension support structures ES1a, ES2a, ES1b, ES2b spaced vertically from the fixed structure FP and extending in the second horizontal direction HD2.

In some example embodiments, the capillary 100 may be supported fixedly by the fixed structure FP and be movable in response to movement of the fixed structure FP. For example, the capillary 100 may generate ultrasonic waves while drawing out the conductive wire CW to a region adjacent to the substrate PS.

In some example embodiments, the first wire holder 200 may be supported fixedly by the first, second, third, and fourth extension support structures ES1a, ES2a, ES1b, ES2b to be movable in response to movement of the first, second, third, and fourth extension support structures ES1a, ES2a, ES1b, ES2b. For example, the first wire holder 200 may be a structure configured to selectively hold the conductive wire CW. For example, the first wire holder 200 may be in contact with the conductive wire CW to secure the conductive wire CW in order to limit the conductive wire CW from detaching from the capillary 100.

In some example embodiments, the wire supply portion 300 may include a spool 310 configured to provide the conductive wire CW and a plurality of wire guides 320 configured to guide the conductive wire CW to be transferred from the spool 310 to the capillary 100.

The plurality of wire guides 320 may include a first guide 320a, a second guide 320b, a third guide 320c, and a fourth guide 320d. For example, the first guide 320a and the second guide 320b may be adjacent to the spool 310 and may control a movement path and a movement speed of the conductive wire CW provided from the spool 310. The third guide 320c may change the movement path of the conductive wire CW from a generally horizontal direction (e.g., along HD1) to the vertical direction VD, and the fourth guide 320d may maintain a constant tension of the conductive wire CW. For example, the fourth guide 320d may be an air guide that blows air onto the conductive wire CW to maintain a straightness (or tension) of the conductive wire CW. Additionally, the fourth guide 320d may be adjacent to the first wire holder 200 to restrict movement of the conductive wire CW in order to keep the conductive wire CW in a constant position.

While only four guides are illustrated in the figures, it will be understood that the number, shape, and arrangement of the guides are provided as an example, and example embodiments are not limited thereto.

Hereinafter, the first wire holder 200 will be described in detail.

Referring to FIGS. 2 to 6A, the first wire holder 200 may include a pair of clamps 210 having a first clamp 210a and a second clamp 210b that are configured to hold the conductive wire CW. The first wire holder 200 may further include a pair of rotation driving mechanisms 240 configured to rotate the pair of clamps 210.

For example, a spacing distance SD (FIG. 3) between the first clamp 210a and the second clamp 210b may be 70 μm (or about 70 μm). However, it will be appreciated that the spacing distance SD is an example, and example embodiments are not limited thereto, and the spacing distance can be changed depending on application and/or design.

In some example embodiments, the pair of clamps 210 may include the first clamp 210a and the second clamp 210b that are spaced apart in the first horizontal direction HD1 with the conductive wire CW interposed therebetween to clamp the conductive wire CW.

In some example embodiments, the first clamp 210a may include a first support body 211a having a polygonal column shaped and having a plurality of first contact surfaces CS1 (FIG. 6A), a first rotation shaft 212a protruding from both end portions of the first support body 211a on a central axis of the first support body 211a, and a pair of first fixing portions 213a connected to the first support body 211a to secure the first support body 211a.

The first support body 211a may include a first surface S31a and a second surface S32a opposite each other. The first support body 211a may include a first center recess CR1 that penetrates the first surface S31a and the second surface S32a, and a plurality of first outer recesses ER1 respectively provided on the first surface S31a and the second surface S32a to surround the first center recess CR1. For example, the first support body 211a may include ceramic, sapphire, glass, diamond, or the like.

The plurality of first contact surfaces CS1 of the first support body 211a may include a first clamping surface WS1 and at least one second clamping surface SS1. For example, the first clamping surface WS1 may be referred to as a working surface in contact with the conductive wire CW and the at least one second clamping surface SS1 may be a working surface of the first clamp 210a that is not in contact with the conductive wire CW. For example, if a foreign substance (or debris, contaminants, etc.) is attached to the first clamping surface WS1, the first clamp 210a may be rotated such that the at least one second clamping surface SS1 is used as a new (or replacement) working surface. Thus, since the first clamp 210a has the plurality of first contact surfaces CS1 (including the first clamping surface WS1), an additional cleaning process may not be performed until all of the plurality of first contact surfaces CS1 are used, thereby reducing the time and/or cost incurred due to the additional cleaning process and improving or optimized or increasing the productivity of the process. Furthermore, since the plurality of first contact surfaces CS1 lengthen the cycle of the cleaning process, a possibility of process errors that may occur due to the cleaning process may be reduced, thereby limiting quality defects.

The first clamping surface WS1 may face the conductive wire CW. The at least one second clamping surface SS1 may be sequentially arranged along a circumference of the first support body 211a from the first clamping surface WS1. For example, the at least one second clamping surface SS1 may be immediately adjacent to the first clamping surface WS1 along a circumference of the first support body 211a. In some example embodiments, the number of first contact surfaces CS1 may be ‘eight’. For example, the first support body 211a may have an octagonal column shape. Thus, the first support body 211a may have an octagonal shape, when viewed in plan view.

The first rotation shaft 212a may extend in the vertical direction VD and penetrate the first support body 211a and the pair of first fixing portions 213a. The first rotation shaft 212a may penetrate the first support body 211a to be coupled with the first support body 211a such that the first rotation shaft 212a rotates together with the first support body 211a.

The first rotation shaft 212a may include a pair of first connection portions CP1a and CP2a at end portions (e.g., at axially opposite ends) of the first rotation shaft 212a. The pair of first connection portions CP1a and CP2a may be connected with the first and second extension support structures ES1a and ES2a of the body portion BP, respectively, and may rotate about its own axis parallel with a first central extension line EL1 of the first rotation shaft 212a.

The first rotation shaft 212a may have a shape corresponding to the first center recess CR1 of the first support body 211a. Thus, the first rotation shaft 212a may be integrally coupled with the first support body 211a. For example, the first support body 211a may be rotatable by a desired angle in a circumferential direction with respect to the first central extension line EL1 in response to rotation of the first rotation shaft 212a. For example, the desired angle may be within a range of 0 degrees to 360 degrees. However, example embodiments are not limited thereto, and the desired angle may be varied depending on application and/or design.

The pair of first fixing portions 213a may include a first upper fixing portion 213a-1 that is connected to the first surface S31a of the first support body 211a and a first lower fixing portion 213a-2 that is connected to the second surface S32a of the first support body 211a. For example, each of the first upper fixing portion 213a-1 and the first lower fixing portion 213a-2 may include a plurality of first connection structures CB1 that are provided on a surface facing the first support body 211a and are fastened to the plurality of first outer recesses ER1 of the first support body 211a, respectively. In some example embodiments, the plurality of first connection structures CB1 may be protrusions (e.g., shaped as bumps) that are respectively received into correspondingly shaped plurality of first outer recesses ER1.

The first upper fixing portion 213a-1 may include a first upper support portion SP1a provided on the first surface S31a of the first support body 211a and a first upper extension portion EP1a extending in the second horizontal direction HD2 from the body portion BP of the wire supply module 40 to the first upper support portion SP1a. For example, the first upper fixing portion 213a-1 may be detachably mounted on the first support body 211a based on movement of the first upper extension portion EP1a.

The first lower fixing portion 213a-2 may include a first lower support portion SP2a provided on the second surface S32a of the first support body 211a and a first lower extension portion EP2a extending in the second horizontal direction HD2 from the body portion BP of the wire supply module 40 to the first lower support portion SP2a. For example, the first lower fixing portion 213a-2 may be detachably mounted on the first support body 211a based on movement of the first lower extension portion EP2a.

In some example embodiments, the second clamp 210b may include a second support body 211b having a polygonal column shape and having a plurality of second contact surfaces CS2, a second rotation shaft 212b protruding from both end portions (e.g., axially end portions) of the second support body 211b on a central axis of the second support body 211b, and a pair of second fixing portions 213b connected with the second support body 211b to secure the second support body 211b.

The second support body 211b may have a first surface S31b and a second surface S32b opposite face each other. The second support body 211b may include a second center recess CR2 that penetrates the first surface S31a and the second surface S32a, and a plurality of second outer recesses ER2 respectively provided on the first surface S31a and the second surface S32a to surround the second center recess CR2. For example, the second support body 211b may include ceramic, sapphire, glass, diamond, or the like.

The plurality of second contact surfaces CS2 of the second support body 211b may include a third clamping surface WS2 and at least one fourth clamping surface SS2. For example, the third clamping surface WS2 may be a working surface in contact with the conductive wire CW, and the at least one fourth clamping surface SS2 may be a working surface of the plurality of second contact surfaces CS2 that is not in contact with the conductive wire CW. For example, if a foreign substance (or debris, contaminants, etc.) is attached to the third clamping surface, the second clamp 210b may be rotated such that the at least one fourth clamping surface is used as a new (or replacement) working surface. Thus, since the second clamp 210b has the plurality of second contact surfaces CS2, an additional cleaning process may not be performed until all of the plurality of second contact surfaces CS2 are used, thereby reducing the time and/or cost incurred due to the additional cleaning process and improving or optimized or increasing the productivity of the process. Furthermore, since the plurality of second contact surfaces CS2 lengthen the cycle of the cleaning process, a possibility of process errors that may occur due to the cleaning process may be reduced, thereby limiting quality defects.

The third clamping surface WS2 may face the conductive wire CW. The at least one fourth clamping surface SS2 may be sequentially arranged along a circumference of the second support body 211b from the third clamping surface WS2. For example, the at least one fourth clamping surface SS2 may be immediately adjacent to the third clamping surface WS2 along a circumference of the second support body 211b. In some example embodiments, the number of second contact surfaces CS2 may be “eight”. For example, the second support body 211b may have an octagonal column shape. Thus, the second support body 211b may have an octagonal shape, when viewed in plan view. For example, a pair of first support bodies 211 may include a first support body 211a and a second support body 211b having an octagonal shape when viewed in plan view.

The second rotation shaft 212b may extend in the vertical direction (VD) to penetrate the second support body 211b and the pair of second fixing portions 213b. The second rotation shaft 212b may penetrate the second support body 211b to be coupled with the second support body 211b such that the second rotation shaft 212b rotates together with the second support body 211b.

The second rotation shaft 212b may include a pair of second connection portions CP1b and CP2b at axially end portions of the second rotation shaft 212b. The pair of second connection members CP1b, CP2b may be connected to the third and fourth extension support portions ES1b, ES2b of the body portion BP, respectively, and may rotate about its own axis parallel with a second central extension line EL2 of the second rotation shaft 212b.

The second rotation shaft 212b may have a shape corresponding to the second center recess CR2 of the second support body 211b. Thus, the second rotation shaft 212b may be integrally coupled with the second support body 211b. For example, the second support body 211b may be rotatable by a desired angle in a circumferential direction with respect to the second central extension line EL2 in response to rotation of the second rotation shaft 212b. For example, the desired angle may be within the range of 0 degrees to 360 degrees. However, example embodiments are not limited thereto, and the desired angle can be varied depending on application and/or design.

The pair of second fixing portions 213b may include a second upper fixing portion 213b-1 that is connected to the first surface S31b of the second support body 211b and a second lower fixing portion 213b-2 that is connected to the second surface S32b of the second support body 211b. For example, each of the second upper fixing portion 213b-1 and the second lower fixing portion 213b-2 may have a plurality of second connection structures CB2 that are provided on a surface facing the second support body 211b and are fastened to the plurality of second outer recesses ER2 of the second support body 211b, respectively.

The second upper fixing portion 213b-1 may include a second upper support portion SP1b provided on the first surface S31a of the second support body 211b and a second upper extension portion EP1b extending in the second horizontal direction HD2 from the body portion BP of the wire supply module 40 to the second upper support portion SP1b. For example, the second upper fixing portion 213b-1 may be detachably mounted on the second support body 211b based on movement of the second upper extension EP1b.

The second lower fixing portion 213b-2 may include a second lower support portion SP2b provided on the second surface S32a of the second support body 211b and a second lower extension portion EP2b extending in the second horizontal direction HD2 from the body portion BP of the wire supply module 40 to the second lower support portion SP2b. For example, the second lower fixing portion 213b-2 may be detachably mounted on the second support body 211b based on movement of the second lower extension portion EP2b.

The first clamp 210a and the second clamp 210b may be spaced apart from each other in the first horizontal direction (HD1) with the conductive wire CW therebetween. For example, the first clamping surface WS1 of the first clamp 210a and the third clamping surface WS2 of the second clamp 210b may be arranged to face each other with the conductive wire CW interposed therebetween. The first clamp 210a and the second clamp 210b may be moved in the first horizontal direction HD1 such that the first clamping surface WS1 of the first clamp 210a and the third clamping surface WS2 of the second clamp 210b come into contact with the conductive wire CW to clamp the conductive wire CW. Thus, the conductive wire CW may be limited from moving out of its position from the capillary 100 during the wire bonding process.

In some example embodiments, the pair of rotation driving mechanisms 240 may be provided adjacent to the pair of clamps 210 and may have shapes corresponding to the pair of clamps 210 to rotate the pair of clamps 210.

The pair of rotation driving mechanisms 240 may be movable along the second horizontal direction HD2 to come into contact with the pair of clamps 210. Each of the pair of rotation driving mechanisms 240 may include a gripper at end portion, which is detachably coupled with the corresponding one of the pair of clamps 210. For example, the gripper of each of the pair of clamps may have a shape corresponding to the corresponding rotation shafts 212a, 212b of each of the pair of clamps 210. By rotating the grippers, the rotation shafts 212a, 212b and the support bodies 211a, 211b integrally coupled with the rotation shafts 212a, 212b may be rotated together.

FIGS. 6B to 6D are views illustrating various shapes of a pair of clamps according to some example embodiments.

Referring to FIG. 6B, each of the pair of second support bodies 211-1 may have a hexagonal shape, when viewed in plan view. For example, the number of each of the plurality of first contact surfaces CS1 of the third support body 211-1a and the plurality of second contact surfaces CS2 of the fourth support body 211-1b may be ‘6’. Thus, each of the pair of second support bodies 211-1 has a relatively larger contact surface, thereby reducing a possibility that the conductive wire CW be detached or dislodged from the pair of second support bodies 211-1.

Referring to FIG. 6C, each of the pair of third support bodies 211-2 may have a dodecagonal shape, when viewed in plan view. For example, the number of each of the plurality of first contact surfaces CS1 of the fifth support body 211-2a and the plurality of second contact surfaces CS2 of the sixth support body 211-2b may be ‘12’. Thus, each of the pair of third support bodies 211-2 has a relatively larger number of contact surfaces, thereby increasing period of the cleaning processes. Thus, each of the pair of third support bodies 211-2 can increase or optimized or improve a productivity of the process. Additionally, each of the pair of third support bodies 211-2 can reduce a possibility of process errors, thereby limiting or reducing poor quality.

Referring to FIG. 6D, the pair of fourth support bodies 211-3 may include a seventh support body 211-3a that is configured as a concave clamp and an eighth support body 211-3b that is configured as a convex clamp. The seventh support body 211-3a configured as a concave clamp may include a plurality of concave contact surfaces recessed into the seventh support body 211-3a (for example, into a surface of the seventh support body 211-3a) and towards the central axis of the seventh support body 211-3a. The eighth support body 211-3b configured as a convex clamp may include a plurality of convex contact surfaces that protrude outwardly (for example, from a surface of the eighth support body 211-3b) from the central axis of the eighth support body 211-3b. The seventh support body 211-3a includes a plurality of first contact surfaces CS1 inwardly recessed towards a center of the seventh support body 211-3a. The eight support body 211-3b includes a plurality of second contact surfaces CS2 outwardly protruding from a center of the eighth support body 211-3b to correspond to the plurality of first contact surfaces CS1. Thus, each of the pair of fourth support bodies 211-3 may have a relatively larger perimeter as compared to a clamp having a polygon shape defined by a plurality of straight lines. Thus, each of the pair of fourth support bodies 211-3 may include a relatively larger number of contact surfaces, while each of the contact surfaces may have a relatively greater length.

However, it will be appreciated that example embodiments are not limited thereto, and the shape, size, structure, and other properties of the support bodies can be varied depending on application and/or design.

As described above, the wire bonding apparatus 10 may include a loading portion 20 configured to secure the substrate PS, a heater 30 located at a lower portion of the loading portion 20 and configured to heat the substrate PS, and a wire supply module 40 located at an upper portion of the loading portion 20 and configured to supply conductive wire CW.

The wire supply module 40 may include a capillary 100 configured to draw out the conductive wire CW onto the substrate PS, a wire supply portion 300 configured to supply the conductive wire CW to the capillary 100, and a first wire holder 200 disposed between the capillary 100 and the wire supply portion 300 and configured or designed to hold or secure the conductive wire CW.

The first wire holder 200 may include a pair of clamps 210 spaced apart from each other to clamp the conductive wire CW and a pair of rotation driving mechanism 240 detachably connected with the pair of clamps 210 to rotate the pair of clamps 210.

Each of the pair of clamps 210 may rotate about the respective central axes EL1 and EL2 and may include the plurality of contact surfaces CS1 and CS2 configured to contact with the conductive wires CW.

Accordingly, since the pair of clamps 210 includes the plurality of contact surfaces CS1 and CS2, when foreign substance (or debris, contaminants, etc.) is attached to at least one of the contact surfaces CS1 and CS2, each of the pair of clamps 210 can be rotated to provide a clean surface of the plurality of contact surfaces. Thus, a cleaning process may not be performed on the pair of clamps 210 until all of the plurality of contact surfaces CS1, CS2 have been utilized. Thus, the pair of clamps 210 may improve or optimized or increase the productivity of the process (e.g., reduce process downtime) and may limit the process from becoming inaccurate due to frequent cleaning processes.

Hereinafter, a wire bonding method using the wire bonding apparatus 10 in FIG. 1 will be described.

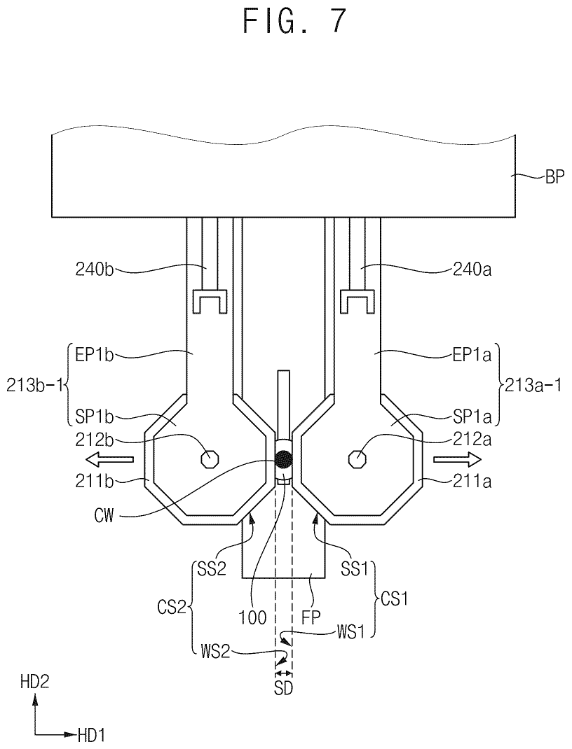

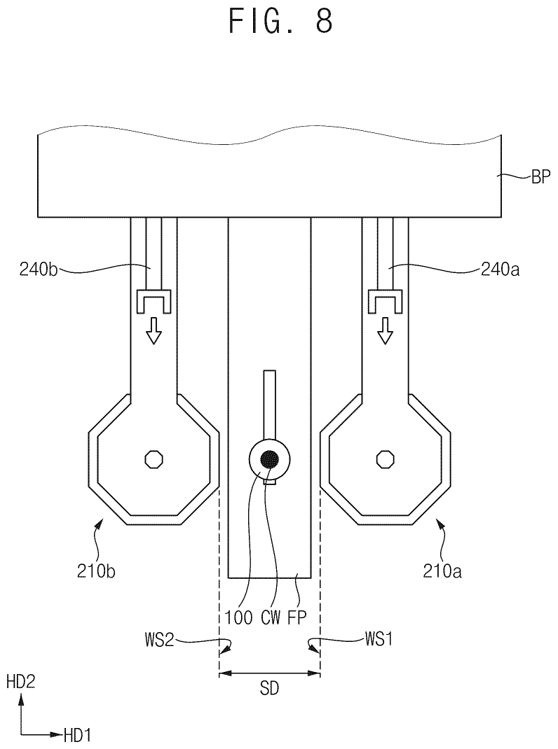

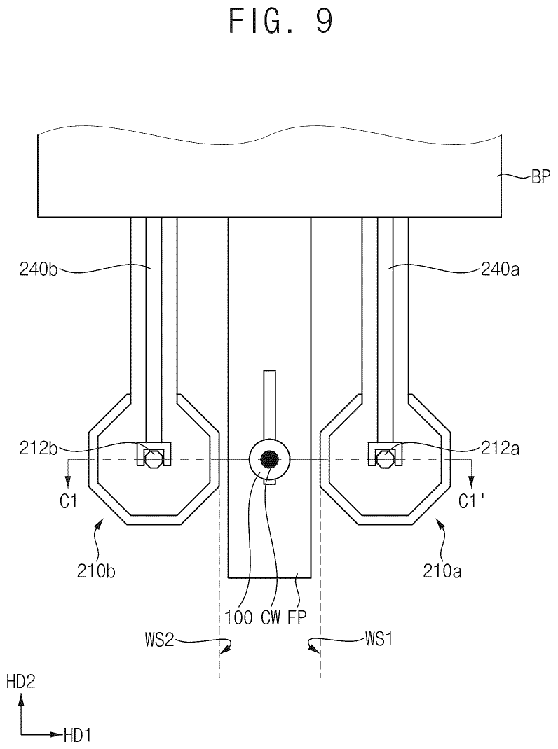

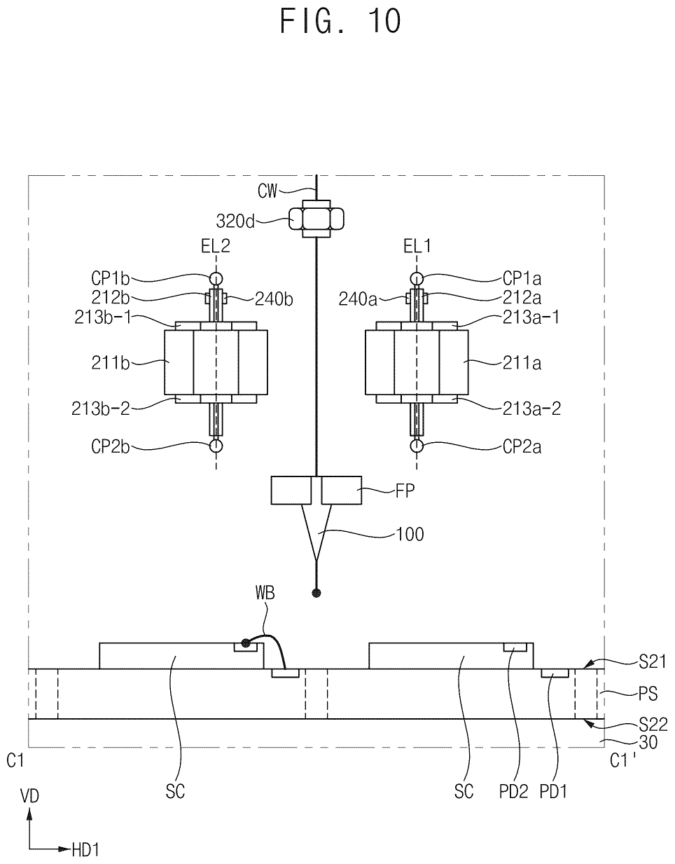

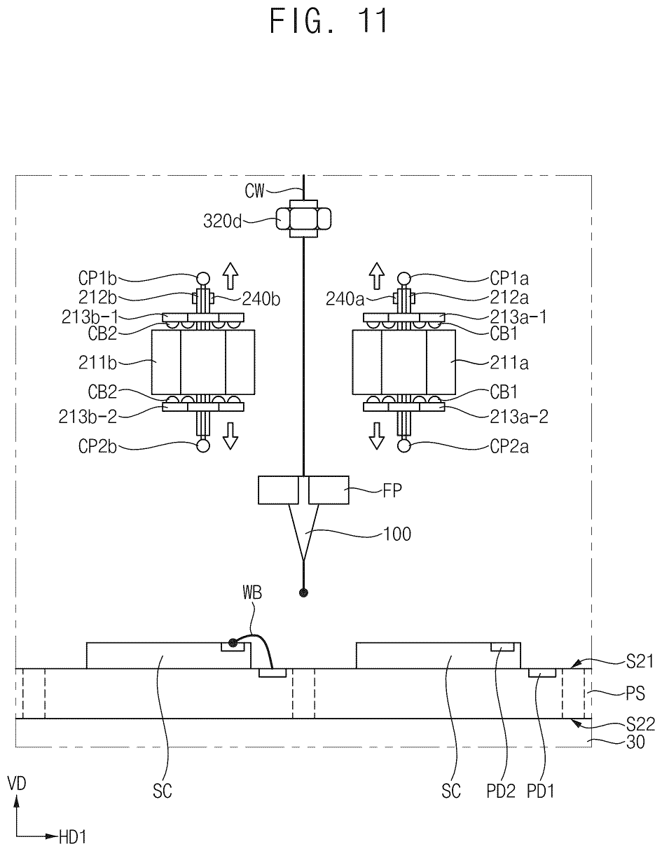

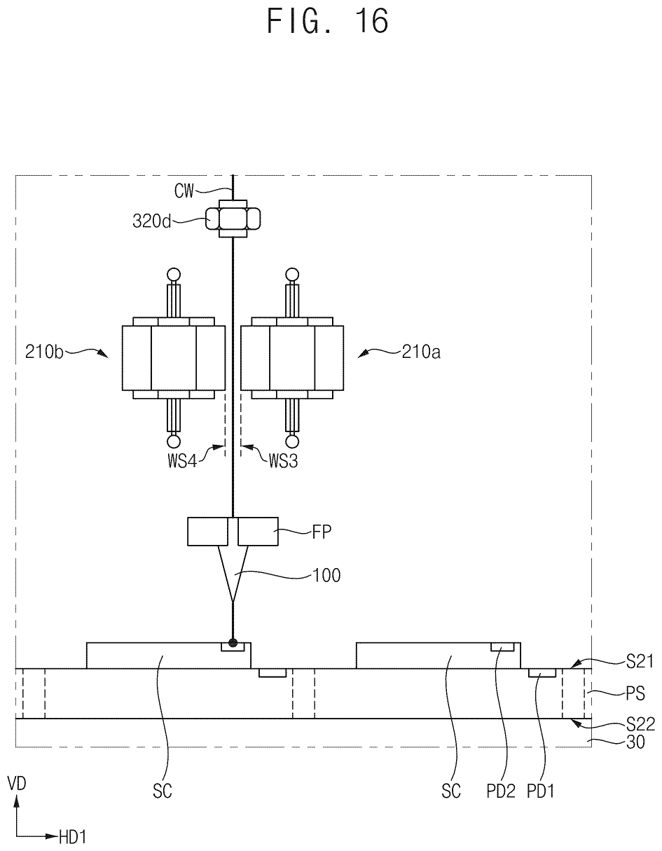

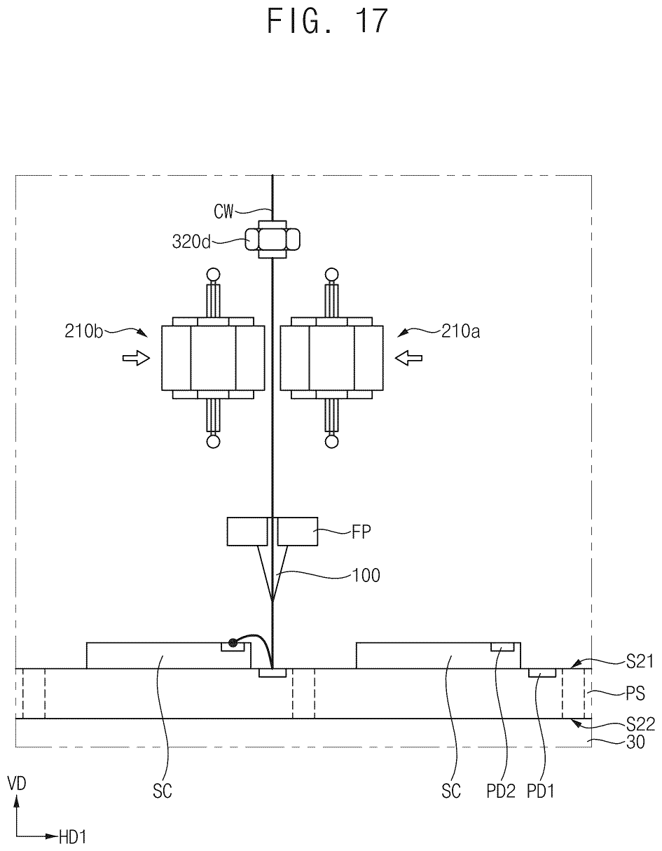

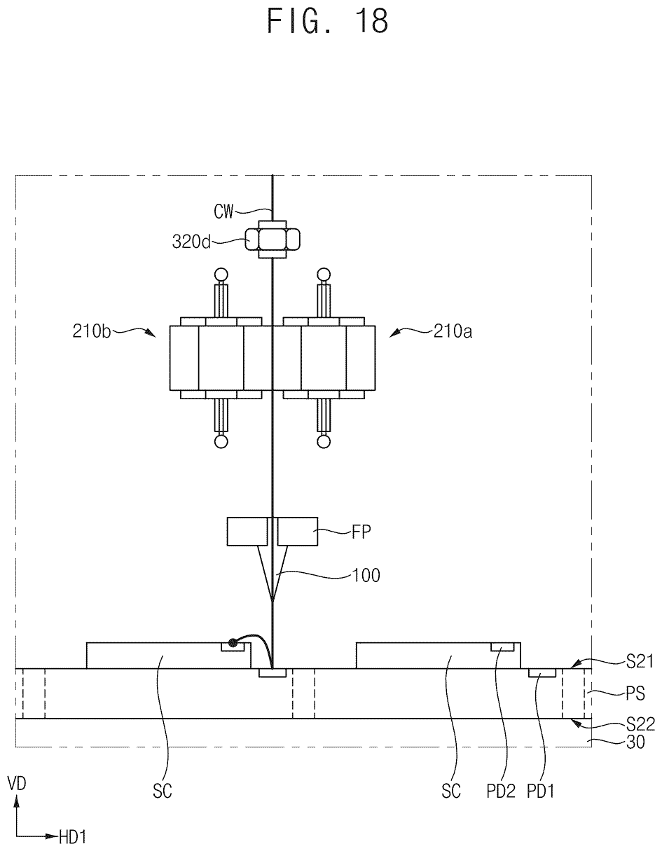

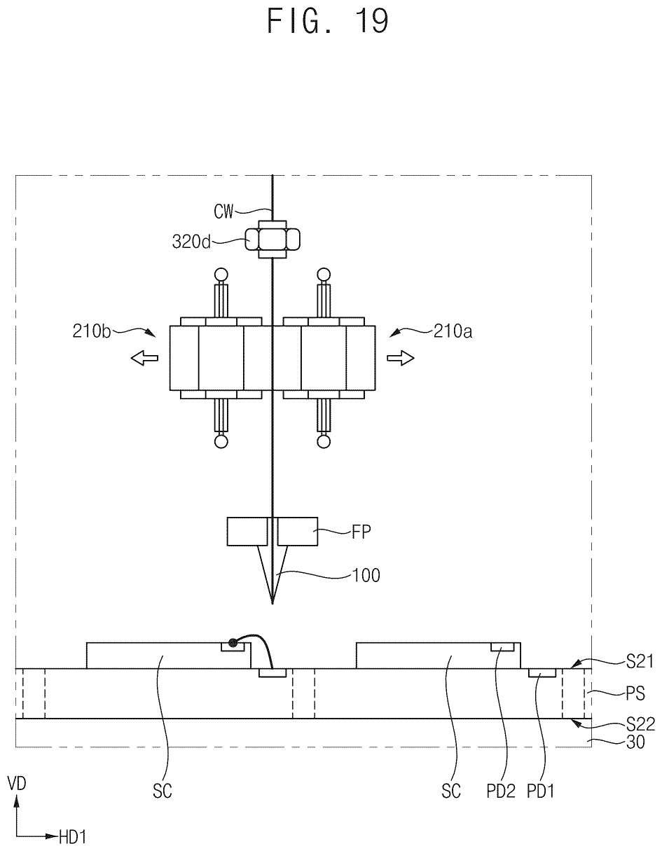

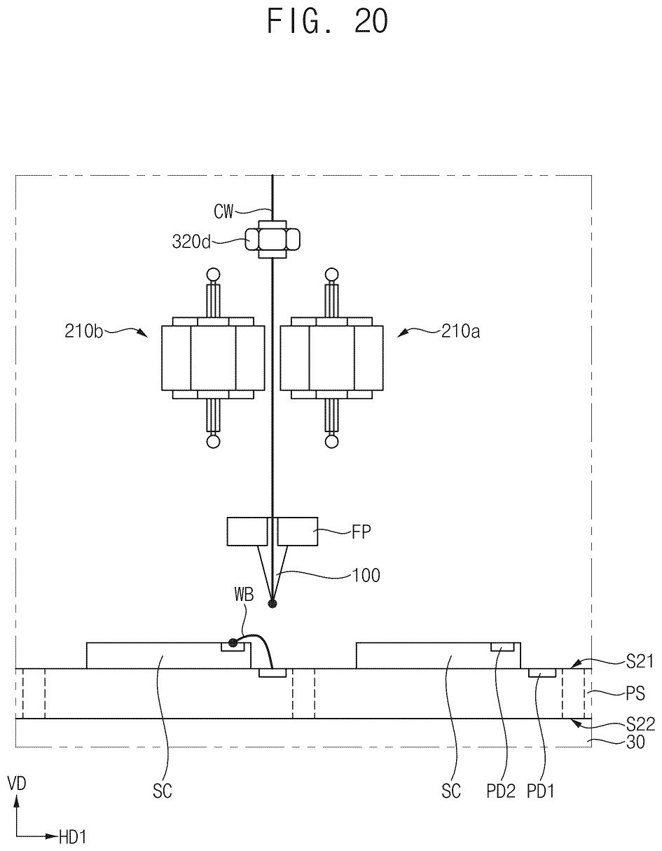

FIG. 7 is a view illustrating a process of moving a pair of clamps. FIGS. 8 to 10 are views illustrating a process of moving a pair of rotation driving mechanisms. FIGS. 11 to 14 are views illustrating a process of rotating a pair of clamps. FIG. 15 is a view illustrating a process of moving a pair of clamps. FIGS. 16 to 20 are views illustrating a process of forming a conductive wire by using a wire bonding apparatus according to some example embodiments.

The wire bonding apparatus in the bonding process illustrated in FIGS. 7 to 20 is same as to similar in some respects to the wire bonding apparatus illustrated in FIGS. 1 to 6A, and therefore may be best understood with reference thereto where like numerals indicate like elements not described again in detail.

Referring to FIG. 7, each of the pair of clamps 210 of the wire supply module 40 may be moved in a first horizontal direction HD1 such that a spacing distance SD between the pair of clamps 210 of the first wire holder 200 is increased. For example, in case that the pair of clamps 210 rotates, the pair of clamps 210 may move until the spacing distance SD of the pair of clamps 210 increases by a distance such that each of the pair of clamps 210 may not contact each other (or collide with each other).

In some example embodiments, the wire supply module 40 may include a capillary 100 configured to draw out (or inject) the conductive wire CW onto the substrate PS, a wire supply portion 300 configured to supply the conductive wire CW to the capillary 100, and a first wire holder 200 disposed between the capillary 100 and the wire supply portion 300 and selectively configured or designed to hold or secure the conductive wire CW.

The first wire holder 200 may include a pair of clamps 210 spaced apart from each other to clamp the conductive wire CW, and a pair of rotation driving mechanism 240 detachably connected with the pair of clamps 210 to rotate the pair of clamps 210.

In some example embodiments, the pair of clamps 210 may include a first clamp 210a and a second clamp 210b spaced apart from each other in a first horizontal direction HD1 with the conductive wire CW interposed therebetween.

In some example embodiments, the first clamp 210a may include a first support body 211a having a polygonal column shape having a plurality of first contact surfaces CS1, a first rotation shaft 212a protruding from both end portions of the first support body 211a along a central axis of the first support body 211a, and a pair of first fixing portions 213a integrally connected with the first support body 211a to secure the first support body 211a. The plurality of first contact surfaces CS1 may include a first clamping surface WS1 and at least one second clamping surface SS1. For example, the first clamping surface WS1 may be referred to as a working surface and is in contact with the conductive wire CW, and the at least one second clamping surface SS1 may be referred to as an extra working surface configured or designed to be in contact with the conductive wire CW when the first clamp 210a is rotated.

In some example embodiments, the second clamp 210b may include a second support body 211b having a polygonal column shape having a plurality of second contact surfaces CS2, a second rotation shaft 212b protruding from both end portions of the second support body 211b along a central axis of the second support body 211b, and a pair of second fixing portions 213b integrally connected to the second support body 211b to secure the second support body 211b. The plurality of second contact surfaces CS2 may include a third clamping surface WS2 and at least one fourth clamping surface SS2. For example, the third clamping surface WS2 may be referred to as a working surface and is in contact with the conductive wire CW, and the at least one fourth clamping surface SS2 may be referred to as an extra working surface configured or designed to be in contact with the conductive wire CW when the second clamp 210b is rotated.

Referring to FIGS. 8 to 10, each of the pair of rotation driving mechanisms 240 may move to the rotation shafts 212a and 212b of each of the pair of clamps 210, and end portion of each of the pair of rotation driving mechanisms 240 may be secured with the rotation shafts 212a and 212b of the pair of clamps 210.

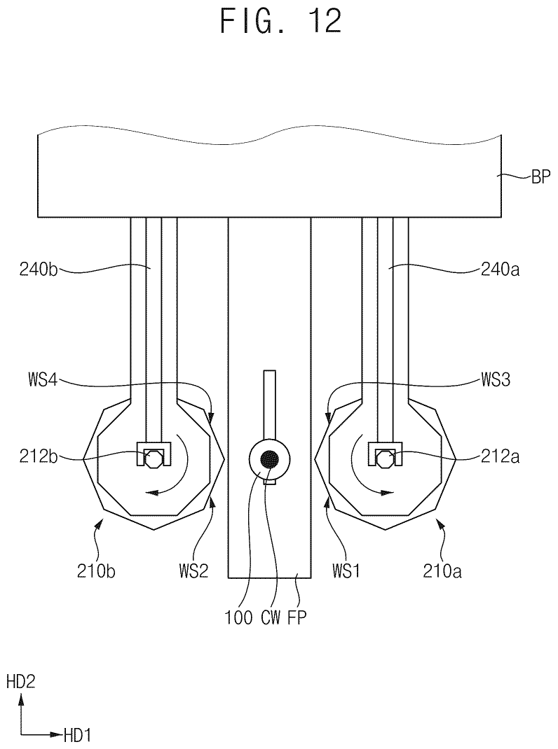

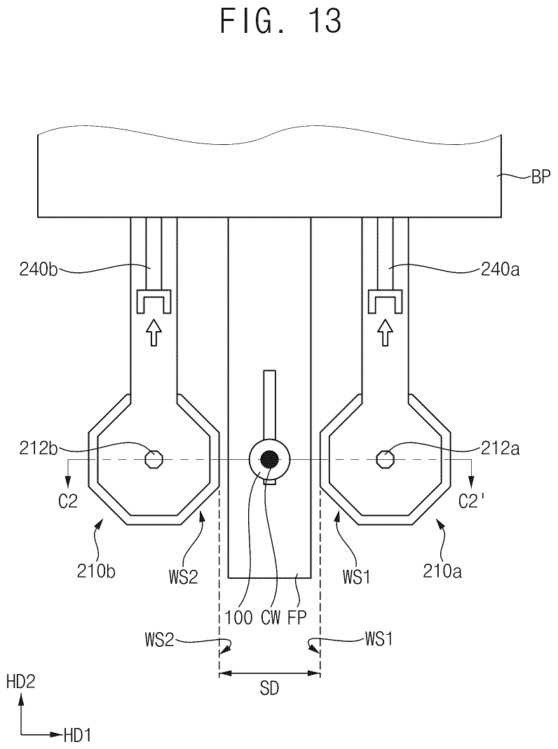

Referring to FIGS. 11 to 14, the fixing portions 213a and 213b of each of the pair of clamps 210 may be separated (FIG. 11) from the support bodies 211a, 211b of each of the pair of clamps 210, and each of the pair of clamps 210 may be rotated (FIG. 12) by utilizing the pair of rotation driving mechanisms 240, and the fixing portions 213a and 213b of each of the pair of clamps 210 may be integrally connected with the support bodies 211a and 211b of each of the pair of clamps 210.

For example, the first clamp 210a of the pair of clamps 210 may include a first clamping surface WS1 as a working surface and a first extra clamping surface WS3 adjacent to the first clamping surface WS1. Further, the second clamp 210b of the pair of clamps 210 may include a third clamping surface WS2 as a working surface and a second extra clamping surface WS4 adjacent to the third clamping surface WS2.

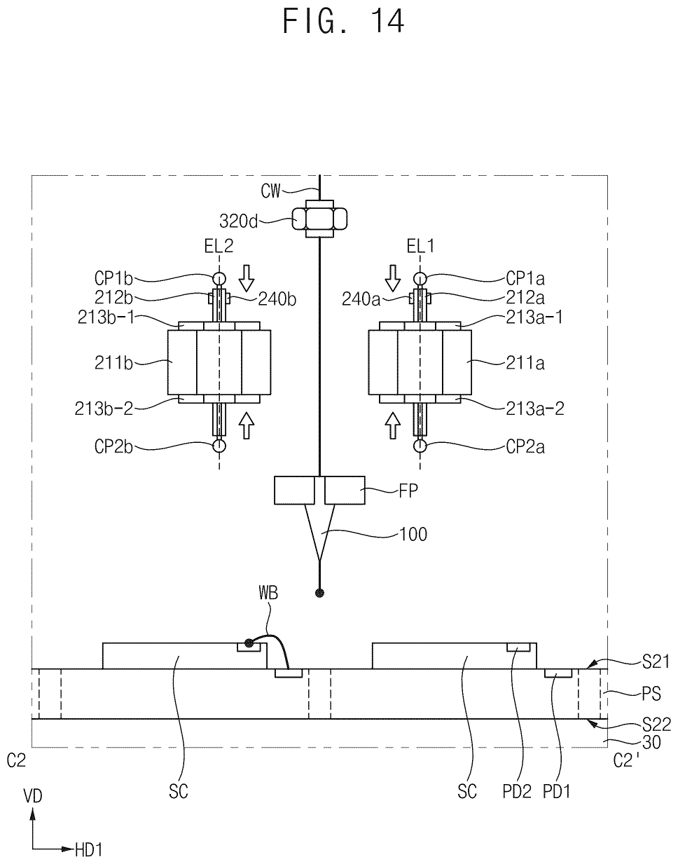

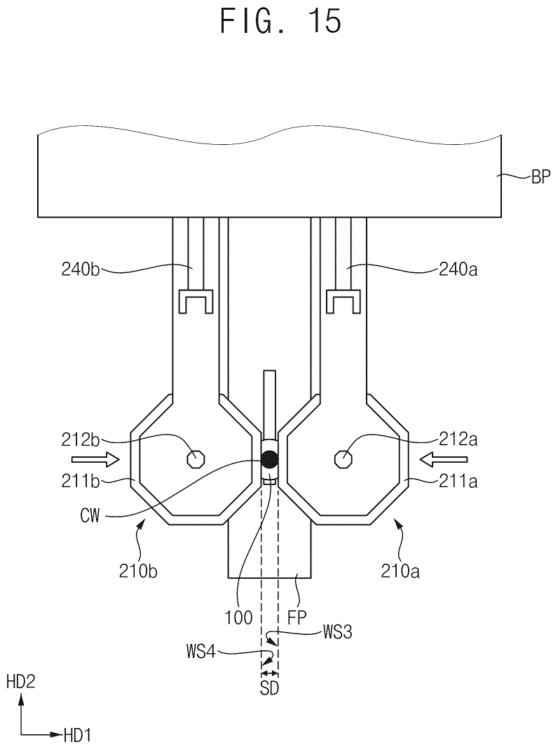

The first clamp 210a and the second clamp 210b can be rotated (FIG. 12) such that the conductive wire CW is disposed (FIG. 13) between the first extra clamping surface WS3 and the second extra clamping surface WS4 by using the pair of rotation driving mechanisms 240. As illustrated in FIG. 14, the fixing portions 213a and 213b of each of the pair of clamps 210 may be contacted with the support bodies 211a, 211b of each of the pair of clamps 210. In some example embodiments, the first clamp 210a and the second clamp 210b may be moved away from each other and then the first clamp 210a and the second clamp 210b may be rotated such that the conductive wire CW is disposed between the first extra clamping surface WS3 and the second extra clamping surface WS4. The first clamp 210a and the second clamp 210b may then be moved towards each other to contact, and thereby secure, the conductive wire therebetween.

Referring to FIG. 15, each of the pair of clamps 210 of the wire supply module 40 may be moved in a first horizontal direction HD1 so that the spacing distance SD between the pair of clamps 210 is decreased.

Referring to FIGS. 16 to 20, in a wire bonding process, bonding wires WB, which connect the plurality of chip pads PD2 and the plurality of substrate pads PD1, may be formed while the conductive wire CW is secured by using the first extra clamping surface WS3 and the second extra clamping surface WS4 of the pair of clamps 210.

For example, the capillary 100 may be moved such that the conductive wires CW, which are injected from the capillary 100, are positioned on the plurality of chip pads PD2, and then the capillary 100 may be moved over the plurality of substrate pads PD1 such that the conductive wires CW, which are injected from the capillary 100, connect the plurality of chip pads PD2 and the plurality of substrate pads PD1. Thereafter, the first extra clamping surface WS3 and the second extra clamping surface WS4 of the pair of clamps 210 may be in contact with the conductive wire CW, respectively, to clamp the conductive wire CW, and the conductive wire CW may be cut from the capillary 100 to form bonding wires WB connecting the plurality of chip pads PD2 and the plurality of substrate pads PD1. For example, ultrasonic waves may be transmitted to the conductive wires CW by the capillary, and the substrate PS may be heated by the heater 30.

As described above, in the wire bonding method according to some example embodiments, the pair of clamps 210 may be rotated such that the conductive wire CW is positioned between the first extra clamping surface WS3 and the second extra clamping surface WS4, thereby the first extra clamping surface WS3 being provided as a working surface instead of the first clamping surface WS1, and the second extra clamping surface WS4 being provided as a working surface instead of the second clamping surface WS2. Further, the first extra clamping surface WS3 and the second extra clamping surface WS4 can be utilized to clamp the conductive wire CW in the bonding process.

Thus, in the wire bonding method according to some example embodiments, cleaning process may be performed after all of the plurality of contact surfaces included in a pair of clamps 210 are used. Thus, the bonding process may improve or optimized or increase the productivity of the process, and reduce the frequency of cleaning and thereby the possibility of introducing process errors due to frequent cleaning processes.

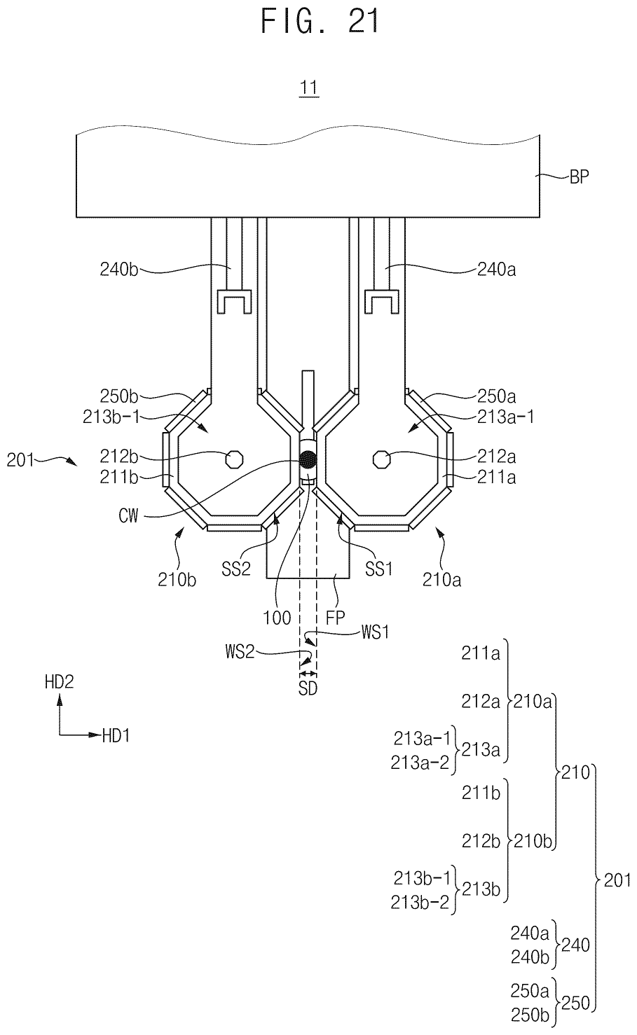

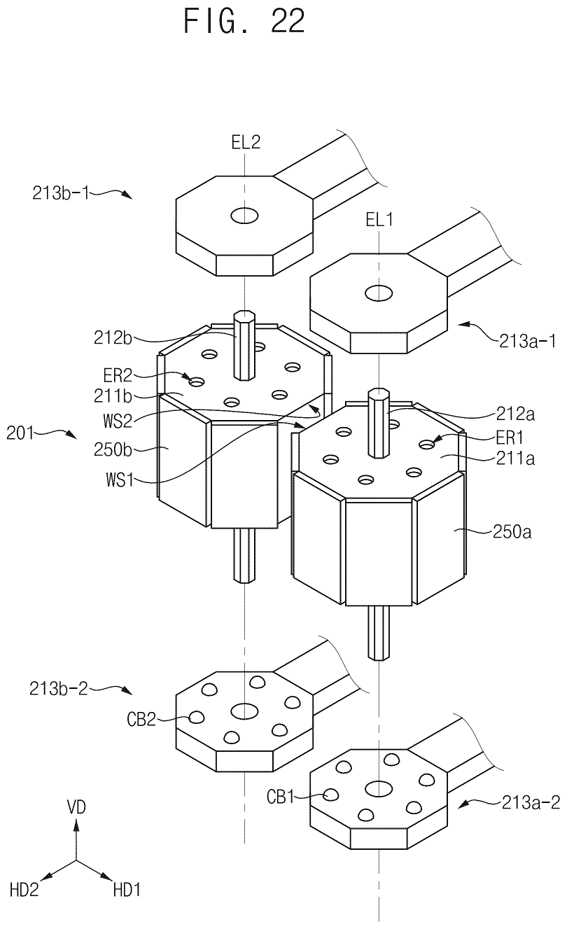

FIG. 21 is a plan view of a second wire holder 201 of a wire bonding apparatus 11 according to some example embodiments. FIG. 22 is a perspective view illustrating the pair of clamps in FIG. 21.

The wire bonding apparatus illustrated in FIGS. 21 and 22 may be same as or similar in some respects to the wire bonding apparatus 10 illustrated in FIGS. 1 to 6A, and therefore may be best understood with reference thereto where like numerals indicate like elements not described again in detail.

Referring to FIGS. 21 and 22 along with FIGS. 1-6A, the wire bonding apparatus 11 may include a loading portion 20 configured to hold a substrate PS, a heater 30 located at a lower portion of the loading portion 20 configured to heat the substrate PS, and a wire supply module 40 located at an upper portion of the loading portion 20 configured to supply conductive wire CW.

The wire supply module 40 may include a capillary 100 configured to draw out (or inject) the conductive wire CW onto the substrate PS, a wire supply portion 300 configured to supply the conductive wire CW to the capillary 100, and a second wire holder 201 disposed between the capillary 100 and the wire supply portion 300 and configured or designed to hold or secure the conductive wire CW.

The second wire holder 201 may include a pair of clamps 210 spaced apart from each other to clamp the conductive wire CW, a pair of rotation driving mechanisms 240 configured to be detachably connected with the pair of clamps 210 for rotating the pair of clamps 210 to clamp the conductive wire CW, and a plurality of protection tapes 250.

In some example embodiments, the plurality of protection tapes 250 may include at least one first protection tape 250a covering a portion of the plurality of first contact surfaces CS1 of the first clamp 210a and at least one second protection tape 250b covering a portion of the plurality of second contact surfaces CS2 of the second clamp 210b. For example, the at least one first protection tape 250a and the at least one second protection tape 250b may be structures configured to reduce or limit contact surfaces of the clamps 210 from being contaminated by contaminants (e.g., airborne contaminants or other contaminants) during a wire bonding process.

The pair of clamps 210 may include a first clamp 210a and a second clamp 210b spaced apart from each other in a first horizontal direction HD1 with the conductive wire CW interposed therebetween.

The first clamp 210a may include a first support body 211a having a polygonal column shape having a plurality of first contact surfaces CS1, a first rotation shaft 212a protruding from one end portion of the first support body 211a along a central axis of the first support body 211a, and a pair of first fixing portions 213a configured to be integrally connected with the first support body 211a to secure the first support body 211a.

The at least one first protection tape 250a may be removably attached to a portion of the plurality of first contact surfaces CS1. For example, the plurality of first contact surfaces CS1 may include a first clamping surface WS1 and at least one second clamping surface SS1. The first clamping surface WS1 may be referred to as a working surface and is in contact with the conductive wire CW, and the at least one second clamping surface SS1 may be an extra working surface configured or designed to be in contact with the conductive wire CW when the first clamp 210a is rotated. The at least one first protection tape 250a may be removably attached to the at least one second clamping surface SS1 to protect the at least one second clamping surface SS1.

The second clamp 210b may include a second support body 211b having a polygonal column shape having a plurality of second contact surfaces CS2, a second rotation shaft 212b protruding from one end portion of the second support body 211b along a central axis of the second support body 211b, and a pair of second fixing portions 213b configured to be integrally connected with the second support body 211b to the second support body 211b.

The at least one second protection tape 250b may be removably attached to a portion of the plurality of second contact surfaces CS2. For example, the plurality of second contact surfaces CS2 may include a third clamping surface WS2 and at least one fourth clamping surface SS2. The third clamping surface WS2 may be referred to as a working surface and is in contact with the conductive wire CW, and the at least one fourth clamping surface SS2 may be an extra working surface configured or designed to be in contact with the conductive wire CW when the second clamp 210b is rotated. The at least one second protection tape 250b may be removably attached to the at least one fourth clamping surface SS2 to protect the at least one fourth clamping surface SS2.

For example, the conductive wire CW may be selectively clamped by the first clamping surface WS1 and the third clamping surface WS2 facing each other during a wire bonding process. In some example embodiments, each of the at least one second clamping surface SS1 and the at least one fourth clamping surface SS2 may be protected by at least one first protection tape 250a and at least one second protection tape 250b. Subsequently, when a contaminant (or debris, foreign substance, etc.) is attached to the first clamping surface WS1 and the third clamping surface WS2, each of the at least one first protection tape 250a and the at least one second protection tape 250b may be removed from the at least one second clamping surface SS1 and the at least one fourth clamping surface SS2, and the conductive wire CW may be selectively secured by using the at least one second clamping surface SS1 and the at least one fourth clamping surface SS2.

As described above, the second wire holder 201 of the wire bonding apparatus 11 may include at least one first protection tape 250a attached to the first clamp 210a and at least one second protection tape 250b attached to the second clamp 210b.

The at least one first protection tape 250a may be detachably attached to the at least one second clamping surface SS1 to protect the at least one second clamping surface SS1 of the first clamp 210a. Further, the at least one second protection tape 250b may be removably attached to the at least one fourth clamping surface SS2 to protect the at least one fourth clamping surface SS2 of the second clamp 210b.

Accordingly, the at least one first protection tape 250a and the at least one second protection tape 250b may limit or reduce the plurality of contact surfaces CS1 and CS2 of each of the pair of clamps 210 from being contaminated by contaminants (e.g., airborne contaminants or other contaminants).

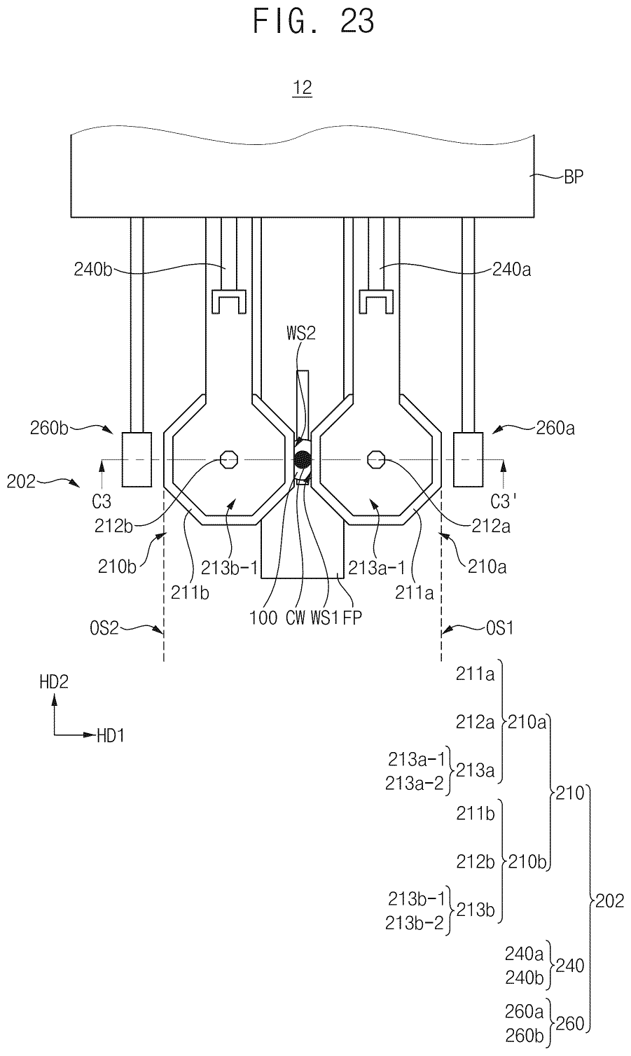

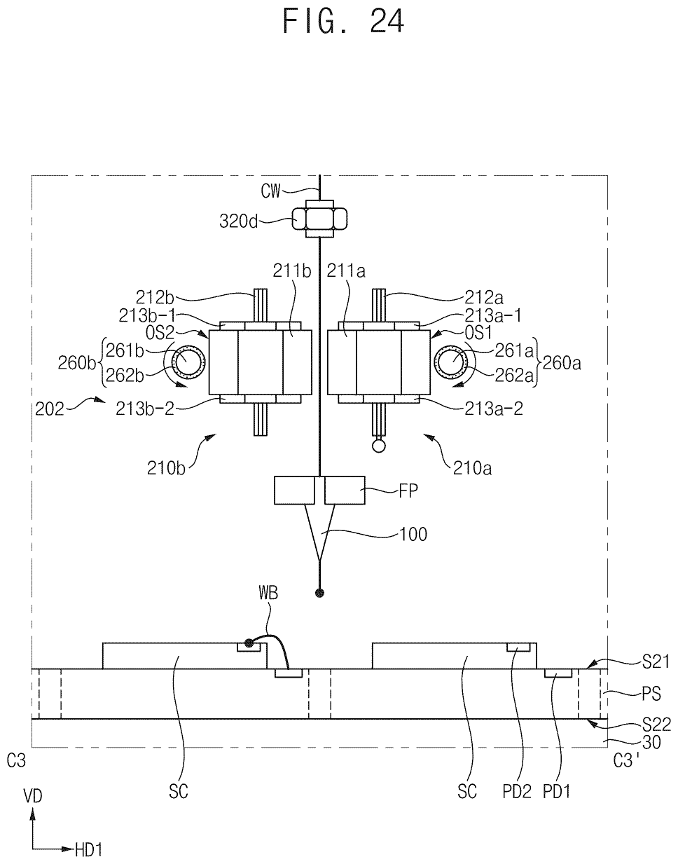

FIG. 23 is a plan view of a third wire holder 202 of a wire bonding apparatus 12 according to some example embodiments. FIG. 24 is a cross-sectional view taken along the line C3-C3′ in FIG. 23.

The wire bonding apparatus illustrated in FIGS. 23 and 24 may be same as or similar in some respects to the wire bonding apparatus illustrated in FIGS. 1 through 6A, and therefore may be best understood with reference thereto where like numerals indicate like elements not described again in detail.

Referring to FIGS. 23 and 24, along with reference to FIGS. 1 through 6A, the wire bonding apparatus 12 may include a loading portion 20 configured to secure a substrate PS, a heater 30 located at a lower portion of the loading portion 20 for heating the substrate PS, and a wire supply module 40 located at an upper portion of the loading portion 20 configured to supply conductive wire CW.

The wire supply module 40 may include a capillary 100 configured to draw out (or inject) the conductive wire CW onto the substrate PS, a wire supply portion 300 configured to supply the conductive wire CW to the capillary 100, and a third wire holder 202 disposed between the capillary 100 and the wire supply portion 300 and configured or designed to hold or secure the conductive wire CW.

The third wire holder 202 may include a pair of clamps 210 spaced apart from each other to clamp the conductive wire CW, a pair of rotation driving mechanisms 240 detachably connected with the pair of clamps 210 to rotate the pair of clamps 210 in order to clamp the conductive wire CW, and a pair of cleaning devices 260 configured to clean the pair of clamps 210.

In some example embodiments, the pair of cleaning devices 260 may include a first cleaning device 260a adjacent to the first clamp 210a and a second cleaning device 260b adjacent to the second clamp 210b. The pair of cleaning devices may be configured to clean the outer faces OS1 and OS2 of a plurality of contact surfaces CS1 and CS2 of the pair of clamps 210. For example, the outer surfaces may be surfaces among the plurality of contact surfaces CS1 and CS2 of the pair of clamps 210 on which contaminants (or foreign substance, debris, etc.) is attached during the wire bonding process.

The first cleaning device 260a may include a first extension movable portion 261a extending from the body portion BP of the wire supply module 40 to a region adjacent to a first outer surface OS1 of the first clamp 210a and a first cleaning portion 262a provided at one end portion of the first extension movable portion 261a adjacent to the first outer surface OS1. For example, the first cleaning portion may include abrasive material, such as diamond paper, to clean or polish the first outer surface OS1 of the first clamp 210a.

The second cleaning device 260b may include a second extension movable portion 261b extending from the body portion BP of the wire supply module 40 to a region adjacent to the second outer surface OS2 of the second clamp 210b and a second cleaning portion 262b provided at one end portion of the second extension movable portion 261b adjacent to the second outer surface OS2. For example, the second cleaning portion may include an abrasive material, such as diamond paper, to clean or polish the second outer surface OS2 of the second clamp 210b.

For example, each of the first cleaning portion 262a of the first cleaning device 260a and the second cleaning portion 262b of the second cleaning device 260b may be rotated after contacting the first outer surface OS1 of the first clamp 210a and the second outer surface OS2 of the second clamp 210b to remove contaminants (or foreign substance, debris, etc.) from the first outer surface OS1 of the first clamp 210a and the second outer surface OS2 of the second clamp 210b. However, it will be understood that example embodiments are not limited thereto. Accordingly, the structure, shape, material, arrangement, etc. of the first cleaning device 260a and the second cleaning device 260b and a cleaning method utilizing the first cleaning device 260a and the second cleaning device 260b can be varied depending on application and/or design.

As described above, the third wire holder 202 of the wire bonding apparatus 12 may further include a pair of cleaning devices 260 configure to clean the pair of clamps 210.

The pair of cleaning devices 260 may include a first cleaning device 260a adjacent to the first clamp 210a and a second cleaning device 260b adjacent to the second clamp 210b.

Accordingly, the pair of cleaning devices 260 may clean the contact surfaces CS1 and CS2 of the pair of clamps 210 during the wire bonding process, thereby increasing the usage cycle (or period) of the pair of clamps 210 and reducing the downtime for maintenance.

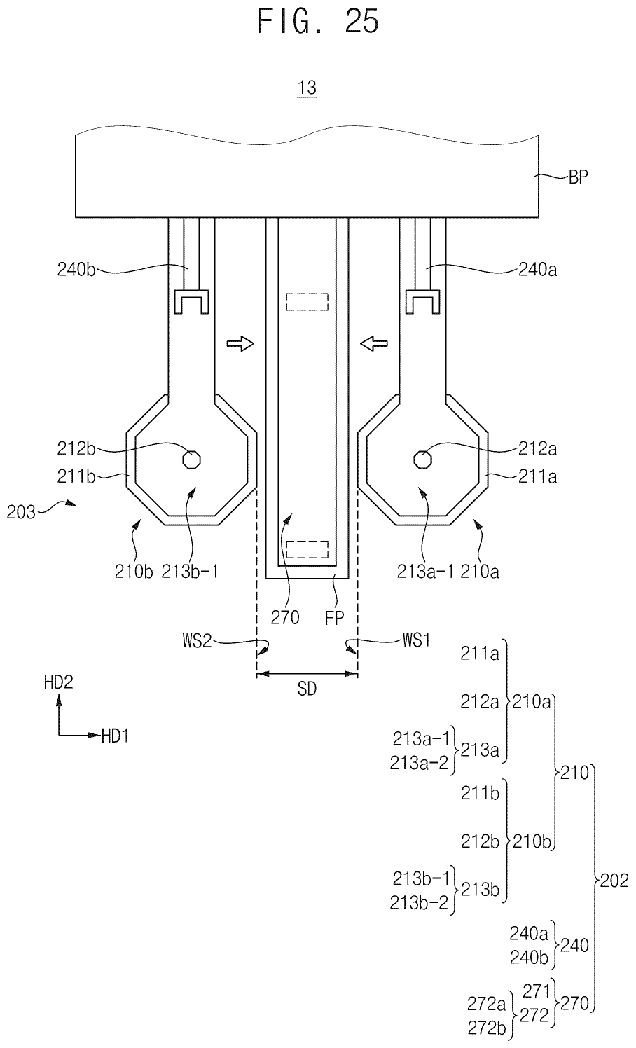

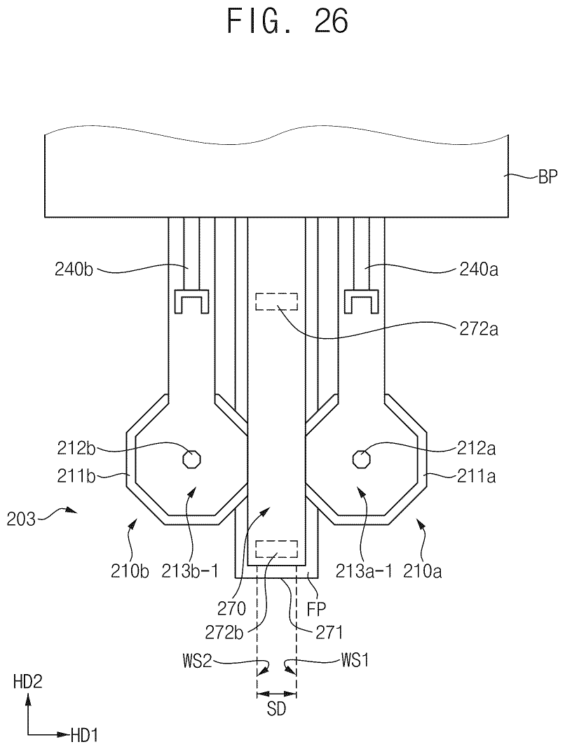

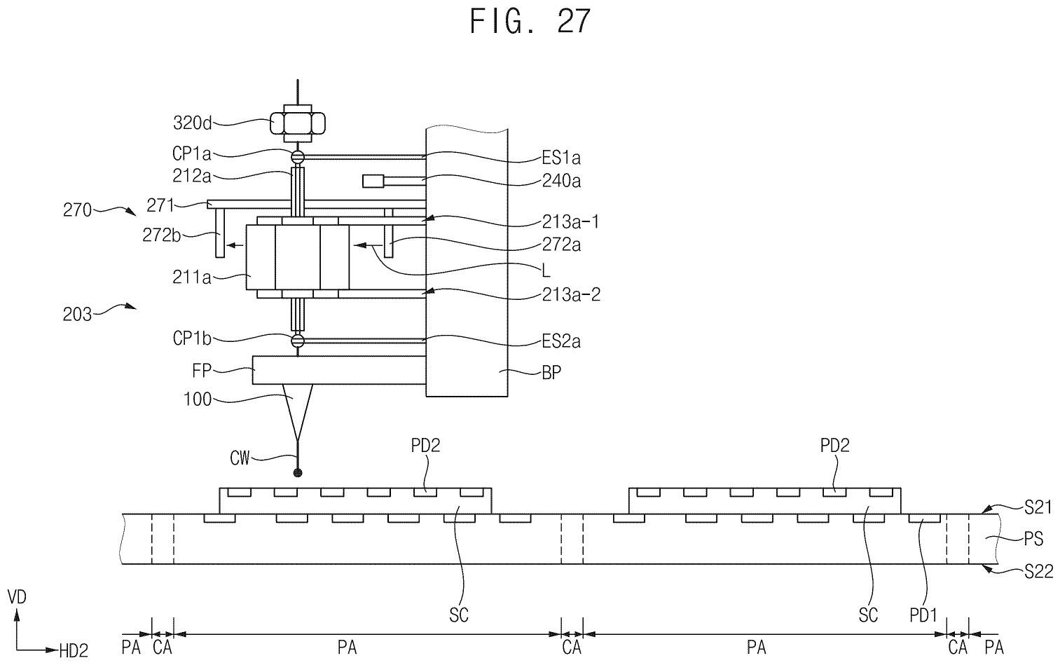

FIG. 25 is a plan view illustrating a wire bonding apparatus 13 according to some example embodiments. FIG. 26 is a plan view of a fourth wire holder 203 of the wire bonding apparatus in FIG. 25. FIG. 27 is a cross-sectional view illustrating the wire bonding apparatus in FIG. 25.

The wire bonding apparatus illustrated in FIGS. 25 through 27 may be same as or similar in some respects to the wire bonding apparatus illustrated in FIGS. 1 through 6A, and therefore may be best understood with reference thereto where like numerals indicate like elements not described again in detail.

Referring to FIGS. 25 to 27 along with FIGS. 1 through 6A, the wire bonding apparatus 13 may include a loading portion 20 configured to secure a substrate PS, a heater 30 located at a lower portion of the loading portion 20 configured to heat the substrate PS, and a wire supply module 40 located at an upper portion of the loading portion 20 configured to supply conductive wire CW.

The wire supply module 40 may include a capillary 100 configured to draw out (or inject) the conductive wire CW onto the substrate PS, a wire supply portion 300 configured to supply the conductive wire CW to the capillary 100, and a fourth wire holder 203 disposed between the capillary 100 and the wire supply portion 300 and configured or designed to hold or secure the conductive wire CW.

The fourth wire holder 203 may include a pair of clamps 210 spaced apart from each other to clamp the conductive wire CW, a pair of rotation driving mechanisms 240 detachably connected with the pair of clamps 210 to rotate the pair of clamps 210 to clamp the conductive wire CW, and a measurement device 270 configured to measure a spacing distance SD of the pair of clamps 210.

In some example embodiments, the measurement device 270 may include a support member 271 extending in the second horizontal direction HD2 from the body portion BP of the wire supply module 40 to pass through an upper portion of the pair of clamps 210 and optical devices 272 disposed on the support member 271 such that the pair of clamps 210 are disposed between the optical devices 272. For example, the measurement device 270 may be a tool or structure configured to measure a separation distance SD of the pair of clamps 210. Further, the support member 271 may be disposed on the body portion BP of the wire supply module 40 such that the support member 271 is movable on the body portion BP of the wire supply module 40 in a first horizontal direction HD1, a second horizontal direction HD2, and a vertical direction VD.

The optical devices 272 may include a light irradiation portion 272a disposed adjacent to the body portion BP of the wire supply module 40 and a light receiving portion 272b disposed on one end portion of the support member 271 facing the light irradiation portion 272a. The pair of clamps 210 may be disposed between the light irradiation portion 272a and the light receiving portion 272b. For example, light L irradiated by the light irradiation portion 272a may be received by the light receiving portion 272b. The measurement device 270 may analyze the light L received by the light receiving portion 272b to measure a spacing distance SD of the pair of clamps 210.

As described above, the fourth wire holder 203 of the wire bonding apparatus 13 may further include the measurement device 270 configured to measure the spacing distance SD of the pair of clamps 210.

The measurement device 270 may include the support member 271 extending in the second horizontal direction HD2 from the body part BP of the wire supply module 40 to pass through the upper portion of the pair of clamps 210 and optical devices 272 disposed on the support member 271 between the pair of clamps 210.

Accordingly, the spacing distance SD of the pair of clamps 210 can be measured by the measurement device 270, thereby reducing errors in the process of rotating the pair of clamps 210, and further avoiding problems that may occur because the spacing distance SD of the pair of clamps 210 is relatively close or spaced apart. For example, when a spacing distance SD of the pair of clamps 210 is relatively larger, the conductive wire CW may be pulled away from the capillary 100 (or detached form the capillary 100). In some example embodiments, the measurement device 270 may reduce or limit the conductive wire CW from being pulled away or stretched from the capillary 100 (or being detached form the capillary 100).

As described herein, any devices, systems, modules, portions, units, controllers, circuits, and/or portions thereof according to any of the example embodiments, and/or any portions thereof (including, without limitation, the controller CO, any portion thereof, or the like may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A wire bonding apparatus, comprising:
a wire supply portion configured to supply a conductive wire;
a capillary configured to draw out the conductive wire from the wire supply portion; and
a wire holder between the capillary and the wire supply portion, the wire holder having a first clamp and a second clamp that are spaced apart from each other and are configured to clamp the conductive wire,
wherein each of the first clamp and the second clamp has a polygonal column shaped support body having a plurality of contact surfaces along a circumference of each of the first clamp and the second clamp, and
wherein the polygonal column shaped support body is configured to rotate in a circumferential direction about a central axis of the polygonal column shaped support body.

2. The wire bonding apparatus of claim 1, wherein each of the first and second clamps includes a rotation shaft that is configured to protrude from one end portion of the polygonal column shaped support body along the central axis of the polygonal column shaped support body.

3. The wire bonding apparatus of claim 2, wherein the wire holder includes a pair of rotation driving mechanisms including a first rotation driving mechanism and a second rotation driving mechanism,
the first rotation driving mechanism is detachably coupled with the rotation shaft of the first clamp and the second rotation driving mechanism is detachably coupled with the rotation shaft of the second clamp, and
each of the first rotation driving mechanism and the second rotation driving mechanism is configured to rotate a corresponding rotation shaft.

4. The wire bonding apparatus of claim 1, wherein the polygonal column shaped support body has at least one of a hexagonal shape, an octagonal shape, and a dodecagonal shape when viewed in plan view.

5. The wire bonding apparatus of claim 1, wherein
the first clamp is a convex clamp having a plurality of convex contact surfaces that protrude outwardly from the central axis of the first clamp,
the second clamp is a concave clamp having a plurality of concave contact surfaces recessed into the second clamp and towards the central axis of the second clamp,
the second clamp is spaced from the first clamp, and
each of the plurality of concave contact surfaces of the second clamp corresponds to one of the plurality of convex contact surfaces of the first clamp.

6. The wire bonding apparatus of claim 1, wherein the first clamp includes a first support body having a plurality of first contact surfaces, and the second clamp includes a second support body having a plurality of second contact surfaces,
wherein the plurality of first contact surfaces include a first clamping surface adjacent to the conductive wire and at least one second clamping surface sequentially adjacent to the first clamping surface along the circumference of the first support body, and
wherein the plurality of second contact surfaces include a third clamping surface opposite the first clamping surface and at least one fourth clamping surface sequentially adjacent to third clamping surface along the circumference of the second support body.

7. The wire bonding apparatus of claim 6, wherein the wire holder includes protection tapes respectively attached to the at least one second clamping surface and the at least one fourth clamping surface, the protection tapes being configured to protect the at least one second clamping surface and the at least one fourth clamping surface.

8. The wire bonding apparatus of claim 1, wherein the wire holder includes a pair of cleaning devices that are respectively adjacent to the first clamp and the second clamp, the pair of cleaning devices being configured to clean the plurality of contact surfaces of each of the first clamp and the second clamp.

9. The wire bonding apparatus of claim 8, wherein the pair of cleaning devices includes an abrasive material configured to polish at least a portion of the plurality of contact surfaces.

10. The wire bonding apparatus of claim 1, wherein the wire holder includes a measurement device between the first clamp and the second clamp and configured to measure a distance between the first clamp and the second clamp.

11. A wire bonding apparatus, comprising:
a loading portion configured to hold a substrate;
a capillary on the loading portion and configured to draw out a conductive wire onto the substrate;
a wire supply portion configured to supply the conductive wire to the capillary; and
a wire holder between the capillary and the wire supply portion, the wire holder having a first clamp and a second clamp that are spaced apart from each other and are configured to clamp the conductive wire,
wherein the first clamp includes a plurality of first contact surfaces and is configured to rotate about a first central extension line passing through a center of the first clamp, and
wherein the second clamp includes a plurality of second contact surfaces spaced from the plurality of first contact surfaces and is configured to rotate about a second central extension line passing through a center of the second clamp.

12. The wire bonding apparatus of claim 11, wherein each of the first and second clamps includes,
a polygonal column shaped support body having a plurality of contact surfaces along a circumference of the polygonal column shaped support body; and
a rotation shaft protruding from one end portion of the polygonal column shaped support body along a central axis of the polygonal column shaped support body.

13. The wire bonding apparatus of claim 12, wherein the wire holder includes a pair of rotation driving mechanisms including a first rotation driving mechanism and a second rotation driving mechanism,
the first rotation driving mechanism is configured to detachably couple with the rotation shaft of the first clamp and the second rotation driving mechanism is configured to detachably couple with the rotation shaft of the second clamp, and
each of the first rotation driving mechanism and the second rotation driving mechanism is configured to rotate a corresponding rotation shaft.

14. The wire bonding apparatus of claim 12, wherein the polygonal column shaped support body has at least one of a hexagonal shape, an octagonal shape, and a dodecagonal shape in plan view.

15. The wire bonding apparatus of claim 11, wherein
the first clamp is a convex clamp having a plurality of convex contact surfaces that protrude outward from the center of the first clamp,
the second clamp is a concave clamp having a plurality of concave contact surfaces recessed into the second clamp,
the second clamp is spaced from the first clamp, and
each of the plurality of concave contact surfaces of the second clamp corresponds to one of the plurality of convex contact surfaces of the first clamp.

16. The wire bonding apparatus of claim 11, wherein the first clamp includes a first support body including the plurality of first contact surfaces, and the second clamp includes a second support body including the plurality of second contact surfaces,
wherein the plurality of first contact surfaces include a first clamping surface adjacent to the conductive wire and at least one second clamping surface sequentially adjacent to the first clamping surface along a circumference of the first support body, and
wherein the plurality of second contact surfaces include a third clamping surface opposite the first clamping surface and at least one fourth clamping surface sequentially adjacent to the third clamping surface along a circumference of the second support body.

17. The wire bonding apparatus of claim 16, wherein the wire holder includes at least one first protection tape attached to the at least one second clamping surface and at least one second protection tape attached to the at least one fourth clamping surface, and
wherein the at least one first protection tape is configured to protect the at least one second clamping surface, and the at least one second protection tape is configured to protect the at least one fourth clamping surface.

18. The wire bonding apparatus of claim 11, wherein the wire holder includes a pair of cleaning devices including a first cleaning device and a second cleaning device,
the first cleaning device is adjacent to the first clamp and the second cleaning device is adjacent to the second clamp, and
the first cleaning device and the second cleaning device are each configured to respectively clean the plurality of first contact surfaces of the first clamp and the plurality of second contact surfaces of the second clamp.

19. The wire bonding apparatus of claim 11, wherein the wire holder includes a measurement device between the first clamp and the second clamp and configured to measure a distance between the first clamp and the second clamp.

20. A wire bonding apparatus, comprising:
a loading portion configured to fix a substrate;
a heater below the loading portion and configured to heat the substrate;
a capillary on the loading portion and configured to draw out a conductive wire onto the substrate;
a wire supply portion including a spool configured to supply the conductive wire and a plurality of guides configured to transfer the conductive wire from the spool to the capillary; and
a wire holder between the capillary and the wire supply portion and configured to hold the conductive wire,
wherein the wire holder includes a first clamp having a plurality of first contact surfaces and a second clamp having a plurality of second contact surfaces,
wherein the first clamp and the second clamp are spaced apart from each other and are configured to clamp the conductive wire, and
wherein each of the first and second clamps includes,
a support body configured to rotate about a central axis of the support body; and
a rotation shaft configured to protrude from one end portion of the support body along the central axis of the support body, the rotation shaft being integral with the support body and configured to rotate with the support body about the central axis the support body.
